(19) United States
(12) Patent Application Publication
(10) Pub. No.: US 2025/0054777 A1
(43) Pub. Date: Feb. 13, 2025

(54) BONDING ASSEMBLY, MICROELECTRONIC COMPONENT AND BONDING BACKPLANE

(71) Applicant: Xiamen Extremely PQ Display Technology Co., Ltd., Xiamen (CN)

(72) Inventor: GANG MA, Xiamen (CN)

(21) Appl. No.: 18/932,551

(22) Filed: Oct. 30, 2024

Related U.S. Application Data
(63) Continuation of application No. PCT/CN2022/105370, filed on Jul. 13, 2022.

(30) Foreign Application Priority Data
Aug. 28, 2024 (CN) 2024221031850

(51) Int. Cl. H01L 21/60; H01L 27/15; H01L 33/36

(52) U.S. Cl. CPC H01L 21/60; H01L 27/15; H01L 33/36

(57) ABSTRACT

A bonding assembly includes: a microelectronic element; a bonding substrate; a chip electrode arranged on a side of the microelectronic element and electrically connected to the microelectronic element; a substrate electrode arranged on a side of the bonding substrate and electrically connected to the bonding substrate. The chip electrode and the substrate electrode can be embedded with each other so that the microelectronic element can be bonded to the bonding substrate. At least one of the chip electrode and the substrate electrode is a receiving structure, and the other is an insertion structure. The receiving structure includes a conductive substrate and an accommodation fixing structure arranged on the conductive substrate, and the accommodation fixing structure can be inserted by the insertion structure and fixed the insertion structure. The provided bonding assembly, microelectronic component and bonding backplane have the characteristics of simple repair process and low repair cost.

### CROSS-REFERENCE TO RELATED APPLICATIONS

This application is a continuation-in-part of International Application No. PCT/CN2022/105370, filed on Jul. 13, 2022, which is herein incorporated by reference in its entirety. This application also claims priority to Chinese patent application No. 202422103185.0, filed to China National Intellectual Property Administration (CNIPA) on Aug. 28, 2024, which is herein incorporated by reference in its entirety.

### TECHNICAL FIELD

This disclosure relates to the technical field of electronic devices, in particular to a bonding assembly, a microelectronic component and a bonding backplane.

### BACKGROUND

At present, micro-light-emitting diode (micro-LED) display technology is widely applied to various display devices. The micro-LED display backplane requires the transfer and bonding of a massive number of micro-LED chips. The post-bonding repair technology is key to achieving mass production. In related art, the repair method generally involves first powering the bonded backplane to locate defective points, then using a laser to remove the chip at the defective points, and finally replacing the chip with a new chip either in an original position or at a spare electrode location. The repaired chip is then bonded to the backplane using either localized or overall heating. This process can easily affect the quality of the solder joints of the surrounding chips that have already been welded, and it presents challenges in terms of repair difficulty and high repair costs.

Therefore, it is urgent to provide a new solution to solve at least some problems of the conventional bonding process of the above-mentioned micro-LED display backplane.

### SUMMARY

Therefore, in order to overcome at least some of the defects in the related art, the disclosure embodiment provides a microelectronic component, a bonding backplane and a bonding assembly, which have the characteristics of simple repair process and low repair cost.

In an aspect, an embodiment of the disclosure provides a bonding assembly, which includes: a microelectronic component and a bonding backplane. The microelectronic component includes a microelectronic element and a chip electrode, and the chip electrode is electrically connected to the microelectronic element. The bonding backplane includes a bonding substrate and a substrate electrode, and the substrate electrode is arranged on a side of the bonding substrate and electrically connected to the bonding substrate. One of the microelectronic component and the bonding backplane is provided with an accommodation fixing structure, and the other of the microelectronic component and the bonding backplane is provided with an insertion structure. The accommodation fixing structure is configured (i.e., arranged and structured) to be capable of being inserted by the insertion structure and fix the insertion structure, so as to make the chip electrode and the substrate electrode be bonded to each other to realize an electrical connection between the microelectronic element and the bonding substrate.

In an embodiment, the accommodation fixing structure is arranged on one of the substrate electrode and the chip electrode, and the insertion structure is arranged on the other of the substrate electrode and the chip electrode.

In an embodiment, the accommodation fixing structure includes a plurality of first nanorods, the plurality of first nanorods are arranged spaced apart from each other, and gaps between the plurality of first nanorods form an accommodation cavity to accommodate the insertion structure.

In an embodiment, the insertion structure includes a plurality of second nanorods, the plurality of second nanorods are arranged spaced apart from each other, and a gap distance between any two adjacent first nanorods of the plurality of first nanorods is equal to a width of a corresponding one of the plurality of second nanorods.

In an embodiment, the accommodation fixing structure includes a conductive side wall, a flexible structure and a conductive sheet. The conductive side wall is enclosed on the conductive substrate to form a filling cavity, and is electrically connected to the conductive substrate. The flexible structure is filled in the filling cavity. The conductive sheet is covered on a side of the conductive side wall facing away from the conductive substrate, and the conductive sheet is electrically connected to the conductive side wall.

In an embodiment, the insertion structure includes: a solder layer and a conductive spike. The conductive spike is arranged on a side of the solder layer, and the conductive spike is capable of penetrating through the conductive sheet and piercing into the flexible structure to be electrically connected to the conductive side wall via the conductive sheet.

In an embodiment, a thickness of the conductive sheet is less than 1 micrometer.

In an embodiment, the microelectronic element includes a first surface and a second surface opposite to each other along a first direction, and side surfaces adjacent to the first surface and the second surface. The microelectronic element further includes a plurality of semiconductor layers layered along the first direction. The chip electrode is at least partially arranged on the side surface of the microelectronic element.

In an embodiment, a substrate groove is defined on the bonding substrate, and the substrate electrode is at least partially located in the substrate groove. The microelectronic element and the chip electrode together serve as the insertion structure, the substrate groove serves as the accommodation fixing structure, and the microelectronic element and the chip electrode are inserted together into the substrate groove to allow the chip electrode and the substrate electrode to be bonded to each other.

In an embodiment, the chip electrode includes a chip electrode side part located on the side surface, the substrate electrode includes a substrate electrode side part covered on a side wall of the substrate groove. The substrate electrode side part is in contact with the chip electrode side part.

In an embodiment, the chip electrode further includes a chip electrode bottom part connected to the chip electrode side part, and the chip electrode bottom part is located on the first surface. The substrate electrode further includes a substrate electrode bottom part connected to the substrate electrode side part and located at a bottom of the substrate groove, and the substrate electrode bottom part is located on a side of the chip electrode bottom part opposite to the microelectronic element and is in contact with the chip electrode bottom part.

In an embodiment, the chip electrode includes a chip electrode side part located on the side surface and a chip electrode bottom part located on the first surface. The substrate electrode includes a substrate electrode side part and a substrate electrode bottom part, and the substrate electrode side part extends from the substrate electrode bottom part along a direction facing away from the bonding substrate. The accommodation fixing structure is arranged on one of the chip electrode bottom part and the substrate electrode bottom part, and the insertion structure is arranged on the other of the chip electrode bottom part and the substrate electrode bottom part, so as to make the chip electrode bottom part and the substrate electrode bottom part be capable of being bonded together, with the chip electrode side part being in contact with the substrate electrode side part and positioning the microelectronic component.

In another aspect, an embodiment of the disclosure provides a microelectronic component, including: a microelectronic element and a chip electrode. The chip electrode is electrically connected to the microelectronic element. The chip electrode includes a conductive substrate and an accommodation fixing structure arranged on the conductive substrate. The accommodation fixing structure is configured to be capable of being inserted by an insertion structure arranged on a substrate electrode of a bonding substrate and fix the insertion structure, so as to make the chip electrode be bonded to the substrate electrode to thereby make the microelectronic element be electrically connected to the bonding substrate.

In an embodiment, the accommodation fixing structure includes a conductive side wall, a flexible structure and a conductive sheet. The conductive side wall is enclosed on the conductive substrate to form a filling cavity, and is electrically connected to the conductive substrate. The flexible structure is filled in the filling cavity. The conductive sheet is covered on a side of the conductive side facing wall away from the conductive substrate, and the conductive sheet is electrically connected to the conductive side wall.

In an embodiment, the accommodation fixing structure includes a plurality of nanorods arranged on a side of the conductive substrate facing away from the microelectronic element. The plurality of nanorods are arranged spaced apart from each other, and gaps between the plurality of nanorods form an accommodation cavity to accommodate the insertion structure.

In an embodiment, the microelectronic element includes a first surface and a second surface opposite to each other along a first direction, and side surfaces adjacent to the first surface and the second surface. The microelectronic element further includes a plurality of semiconductor layers layered along the first direction. The chip electrode is electrically connected to the microelectronic element and is at least partially arranged on the side surface of the microelectronic element.

In an embodiment, the chip electrode includes a chip electrode side part located on the side surface and a chip electrode bottom part arranged on the first surface, the chip electrode bottom part is connected to the chip electrode side part, and the accommodation fixing structure is arranged on the chip electrode bottom part facing away from the first surface.

In an embodiment, the plurality of semiconductor layers each includes a first semiconductor layer, an active layer and a second semiconductor layer. The first semiconductor layer includes the first surface, the second surface and the side surfaces. The active layer covers the first surface and the side surfaces, and the second semiconductor layer covers the active layer.

In an embodiment, the microelectronic element further includes an insulation layer covering the second semiconductor layer. The chip electrode includes a first polar electrode and a second polar electrode. The second polar electrode is electrically connected to the second semiconductor layer by penetrating through the insulation layer. The first polar electrode is insulated with the second semiconductor layer through the insulation layer, and the first polar electrode is electrically connected to the first semiconductor layer. At least a portion of at least one of the first polar electrode and the second polar electrode is arranged on the side surface.

In an embodiment, the plurality of semiconductor layers each includes a first semiconductor layer, an active layer and a second semiconductor layer. The first semiconductor layer includes the first surface, the second surface and the side surfaces. The active layer and the second semiconductor layer are sequentially layered on the first surface. An orthographic area of the active layer on the first surface and an orthographic area of the second semiconductor layer on the first surface are less than an area of the first surface. The chip electrode includes a first polar electrode and a second polar electrode. The second polar electrode is arranged on a side of the second semiconductor layer facing away from the active layer and is electrically connected to the second semiconductor layer. The first polar electrode is at least partially arranged on the side surface and electrically connected to the first semiconductor layer.

Another embodiment of the disclosure provides a bonding backplane including: a bonding substrate and a substrate electrode electrically connected to the bonding substrate. The bonding backplane further includes an accommodation fixing structure, and the accommodation fixing structure is configured to be inserted by an insertion structure of a microelectronic component and fix the insertion structure, so as to make the substrate electrode be bonded to the chip electrode in the microelectronic component to make the bonding substrate be electrically connected to the microelectronic component.

In an embodiment, the substrate electrode includes a conductive substrate and an accommodation fixing structure arranged on the conductive substrate, and the accommodation fixing structure is configured to be capable of being inserted by the insertion structure located on the chip electrode and fix the insertion structure.

In an embodiment, the accommodation fixing structure includes a conductive side wall, a flexible structure and a conductive sheet. The conductive side wall is enclosed on the conductive substrate to form a filling cavity, and is electrically connected to the conductive substrate. The flexible structure is filled in the filling cavity. The conductive sheet is covered on a side of the conductive side wall facing away from the conductive substrate, and the conductive sheet is electrically connected to the conductive side wall.

In an embodiment, the accommodation fixing structure includes: a plurality of nanorods arranged on a side of the conductive substrate facing away from the bonding substrate. The plurality of nanorods are arranged spaced apart from each other, and gaps between the plurality of nanorods form an accommodation cavity accommodate the insertion structure.

In an embodiment, the substrate electrode includes a substrate electrode side part extending along a direction facing away from the bonding substrate, a substrate groove is defined on the bonding substrate, the substrate electrode side part is located on a side wall of the substrate groove, and the substrate groove serves as the accommodation fixing structure.

In an embodiment, the substrate electrode includes a substrate electrode side part and a substrate electrode bottom part, the substrate electrode side part extends from the substrate electrode bottom part along a direction facing away from the bonding substrate, and the accommodation fixing structure is arranged on the substrate electrode bottom part.

The above embodiments of the disclosure have at least one or more of the following beneficial effects. By setting the accommodation fixing structure on the microelectronic component or the bonding backplane, the insertion and fixation of the insertion structure and the accommodation fixing structure can be realized, the chip electrode and the substrate electrode can be bonded without heating and welding the microelectronic component and the bonding backplane, and the electrical connection between the microelectronic element and the bonding substrate can be realized. The whole surface heating welding or wireless heating welding can be carried out after the repair, which can reduce the adverse effects on the surrounding devices during the repair process.

Other aspects and features of the disclosure become apparent through the detailed description of the following attached drawings. It should be noted, however, that the drawings are designed for interpretation purposes only and not as a limitation of the scope of the disclosure. It should also be known that, unless otherwise noted, drawings are not necessarily drawn to scale and that they merely attempt to conceptually illustrate the structures and processes described herein.

### BRIEF DESCRIPTION OF DRAWINGS

Specific embodiments of the disclosure will be described in detail with reference to the attached drawings.

FIG. 1 illustrates a schematic structural diagram of a bonding assembly according to a first embodiment of the disclosure.

FIG. 2 illustrates a schematic structural diagram of a specific embodiment of the bonding assembly illustrated FIG. 1.

FIG. 3 illustrates a schematic structural diagram of another specific embodiment of the bonding assembly illustrated FIG. 2.

FIG. 4 illustrates a schematic flowchart of a repair method for the bonding assembly illustrated FIG. 2.

FIG. 5 illustrates a schematic structural diagram of a bonding assembly according to a second embodiment of the disclosure.

FIG. 6 illustrates a schematic structural diagram of a specific embodiment of the bonding assembly illustrated FIG. 5.

FIG. 7 illustrates a schematic flowchart of a repair method for the bonding assembly illustrated FIG. 6.

FIG. 8 illustrates a schematic structural diagram of a microelectronic component according to a third embodiment of the disclosure.

FIG. 9 illustrates a schematic structural diagram of a microelectronic component according to a fourth embodiment of the disclosure.

FIG. 10 illustrates schematic structural diagram of a bonding backplane according to a fifth embodiment of the disclosure.

FIG. 11 illustrates a schematic structural diagram of a bonding backplane according to a sixth embodiment of the disclosure.

FIG. 12 illustrates a schematic structural diagram of a bonding assembly according to a seventh embodiment of the disclosure.

FIG. 13 illustrates a schematic structural diagram of another bonding assembly according to the seventh embodiment of the disclosure.

FIG. 14 illustrates a schematic structural diagram of the bonding assembly as illustrated FIG. 13 after bonded.

FIG. 15 illustrates a schematic structural diagram of still another bonding assembly according to the seventh embodiment of the disclosure.

FIG. 16 illustrates a schematic structural diagram of the bonding assembly as illustrated FIG. 15 after bonded.

FIG. 17 illustrates a schematic structural diagram of even still another bonding assembly according to the seventh embodiment of the disclosure.

FIG. 18 illustrates a schematic structural diagram of further still another bonding assembly according to the seventh embodiment of the disclosure.

FIG. 19 illustrates a schematic structural diagram of even further still another bonding assembly according to the seventh embodiment of the disclosure.

FIG. 20 illustrates a schematic structural diagram of even more further still another bonding assembly according to the seventh embodiment of the disclosure.

FIG. 21 illustrates a schematic structural diagram of a microelectronic component according to an eighth embodiment of the disclosure.

FIG. 22A illustrates a schematic structural diagram of another microelectronic component according to the eighth embodiment of the disclosure.

FIG. 22B illustrates a schematic structural diagram of still another microelectronic component according to the eighth embodiment of the disclosure.

FIG. 22C illustrates a schematic structural diagram of even still another microelectronic component according to the eighth embodiment of the disclosure.

FIG. 22D illustrates a schematic structural diagram of further still another microelectronic component according to the eighth embodiment of the disclosure.

FIG. 23 illustrates a schematic structural diagram of a bonding backplane according to a ninth embodiment of the disclosure.

FIG. 24 illustrates a schematic structural diagram of another bonding backplane according to the ninth embodiment of the disclosure.

FIG. 25 illustrates a schematic structural diagram of still another bonding backplane according to the ninth embodiment of the disclosure.

FIG. 26 illustrates a structural diagram of even still another bonding backplane according to the ninth embodiment of the disclosure.

### DESCRIPTION OF REFERENCE SIGNS

10: bonding assembly; 11: microelectronic element; 111: first surface; 112: second surface; 113: side surface; 114: semiconductor layer; 1141: first semiconductor layer; 1142: active layer; 1143: second semiconductor layer; 115: insulation layer; 116: transparent electrode; 12: bonding substrate; 121: driving circuit board; 122: pixel definition layer; 123: substrate groove; 13: first embedded electrode (i.e., chip electrode); 13a: first polar electrode; 13b: second polar electrode; 131: chip electrode side part; 132: chip electrode bottom part; 14: second embedded electrode (i.e., substrate electrode); 141: substrate electrode side part; 142: substrate electrode bottom part; 143: accommodation groove; 15: receiving electrode; 151: conductive substrate; 152: accommodation fixing structure; 1521: conductive side wall; 1522: flexible structure; 1523: conductive sheet; 1524: nanorod; 1525: accommodation cavity; 1526: filling cavity; 16: insertion electrode; 161: solder layer; 162: conductive spike; 20: microelectronic component; 30: bonding backplane.

### DETAILED DESCRIPTION OF EMBODIMENTS

In order to make the above objects, features and advantages of the disclosure be more readily understood, specific embodiments of the disclosure will be described in detail with the attached drawings.

In order to make those skilled in the art better understand the technical solutions of the disclosure, the technical solutions in the embodiments of the disclosure will be clearly and completely described below in conjunction with the attached drawings. Apparently, the described embodiments are only some of the embodiments of the disclosure, but not all of the embodiments. Based on the embodiments in the disclosure, all other embodiments obtained by those skilled in the art without creative work should belong to the protection scope of the disclosure.

It should be noted that the terms “first”, “second”, and the like in the description and claims of the disclosure and the drawings are used to distinguish similar objects, and are not necessarily used to describe a specific order or precedence. It should be understood that the terms so used may be interchangeable under appropriate circumstances, so that the embodiments of the disclosure described herein can be implemented in other orders than those illustrated or described herein. Furthermore, the terms “including” and “having” and any variations thereof are intended to cover a non-exclusive inclusion, for example, a process, a method, a system, a product, or an apparatus that includes a series of steps or elements is not necessarily limited to those explicitly listed, but may include other steps or elements not explicitly listed or inherent to the process, the method, the product, or the apparatus.

It should also be noted that the division of multiple embodiments in the disclosure is only for the convenience of description, and should not constitute a special limitation. The features in various embodiments can be combined and referred from each other without contradiction.

In related art, there are mainly two kinds of bonding methods of micro-LED. One is to set an adhesive layer on a driving circuit board, the micro-LED is transferred to the adhesive layer, and the adhesive layer is heated to make an adhesive material adhere to the micro-LED and the bonding connection between the micro-LED and the driving circuit board is realized. The other is to set welding electrodes on the driving circuit board, electrodes of the micro-LED are welded with electrodes on the circuit board by heating and welding. The two kinds of bonding methods have some defects in the bonding repair process of the micro-LED. For example, in the method of setting the adhesive layer, since the adhesive layer fails after the first transfer, the failed adhesive layer on the spare electrode needs to be removed and a new adhesive material needs to be added before a new chip is transferred to the spare electrode. Since the size of the micro-LED is in the micrometer level, it is difficult to remove and supplement the single-point adhesive material. For the method of heating and welding, the entire panel needs to be heated and welded during the first transfer, the repair point needs to be heated for the second time if a new chip is bonded during the repair, and the thermal effect of heating and welding may affect the adjacent point, so that the welding point is melted here, affecting the welding quality. For this purpose, a new bonding scheme is provided to address at least some of the above defects.

### First Embodiment

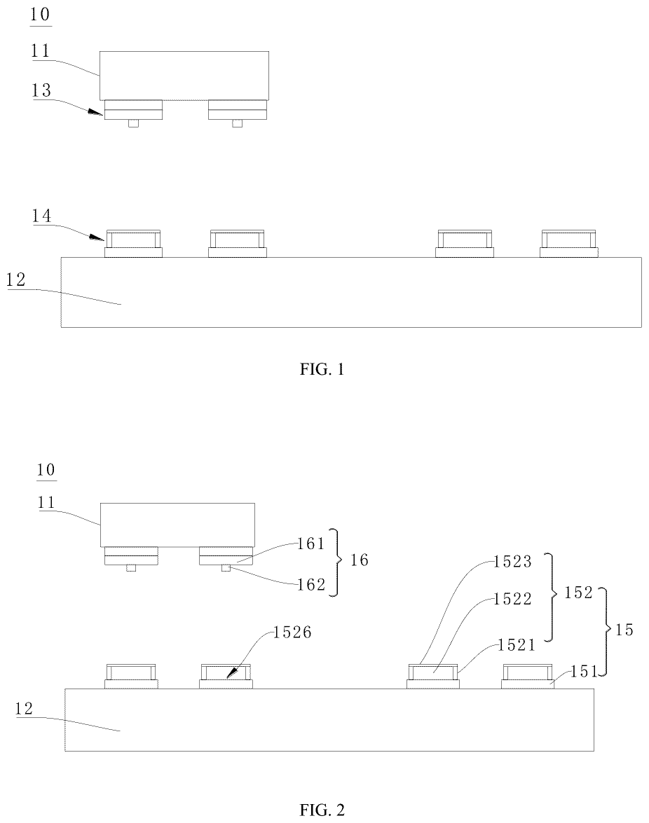

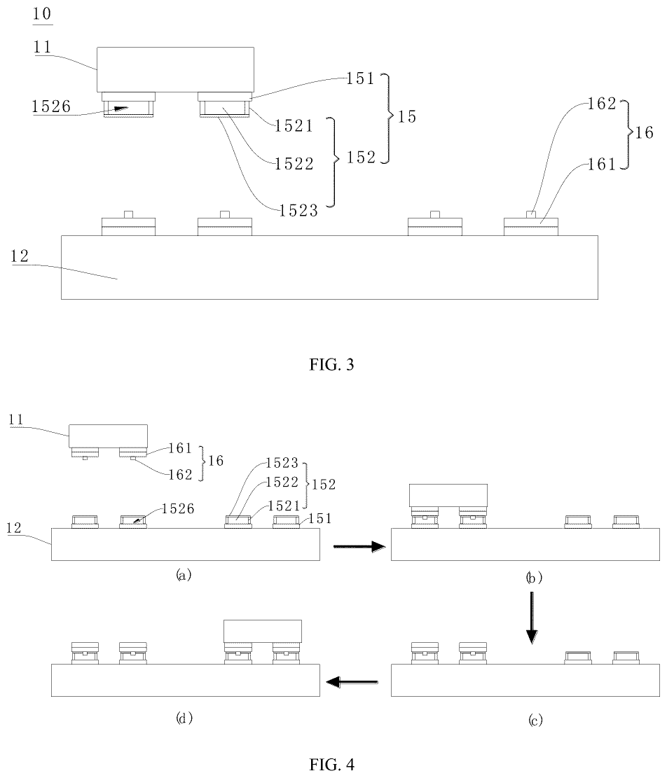

As illustrated FIG. 1, the first embodiment of the disclosure provides a bonding assembly 10 including a microelectronic element 11, a bonding substrate 12, a first embedded electrode (i.e., chip electrode) 13 arranged on a side of the microelectronic element 11 and electrically connected to the microelectronic element 11, and a second embedded electrode (i.e., substrate electrode) 14 is arranged on a side of the bonding substrate 12 and electrically connected to the bonding substrate 12. In this embodiment, the combination of the microelectronic element 11 and the first embedded electrode 13 is a specific implementation of the microelectronic component, and the bonding substrate 12 and the second embedded electrode 14 are a specific implementation of the bonding backplane. The microelectronic component and the bonding backplane can be embedded with each other through the first embedded electrode 13 and the second embedded electrode 14, so that the first embedded electrode 13 and the second embedded electrode 14 are bonded together, so as to realize the electrical connection between the microelectronic element 11 and the bonding substrate 12. The first embedded electrode 13 and the second embedded electrode 14 can be embedded with each other so that the microelectronic element 11 can be bonded to the bonding substrate 12. At least one of the first embedded electrode 13 and the second embedded electrode 14 acts as a receiving electrode 15 and the other of the first embedded electrode 13 and the second embedded electrode 14 acts as an insertion electrode 16. The receiving electrode 15 includes a conductive substrate 151 and an accommodation fixing structure 152 arranged on the conductive substrate 151. The accommodation fixing structure 152 can be inserted into the insertion electrode 16 and fixed the insertion electrode 16. The microelectronic element 11, for example, is a micro light-emitting device, specifically, for example, a micro-LED chip. As illustrated FIG. 1, a flip-chip micro-LED chip has a P-type semiconductor layer and an N-type semiconductor layer, and the P-type semiconductor layer and the N-type semiconductor layer are each provided with a first embedded electrode 13. The corresponding bonding substrate 12, for example, is a micro-LED driving circuit board, and the bonding substrate 12 is provided with two second embedded electrodes 14 corresponding to one micro-LED chip. The bonding substrate 12 is provided with multiple second embedded electrodes which can bond multiple micro-LED chips. Of course, FIG. 1 only illustrates the structure of the flip-chip micro-LED chip for the microelectronic element 11. The microelectronic element 11 can also be, for example, a vertical micro-LED chip. For example, a first embedded electrode 13 is provided on a P-type semiconductor layer of the vertical micro-LED chip, a second embedded electrode 14 is provided on the bonding substrate 12 corresponding to a bonding position of the micro-LED chip. As illustrated FIG. 2, for example, the second embedded electrode 14 on the bonding substrate 12 serves as the receiving electrode 15 and the first embedded electrode 13 on the microelectronic element 11 serves as the insertion electrode 16. On the contrary, in some embodiments, as illustrated FIG. 3, the first embedded electrode 13 on the microelectronic element 11 can be used as the receiving electrode 15 and the second embedded electrode 14 on the substrate 12 can be used as the insertion electrode 16. Alternatively, the first embedded electrode 13 and the second embedded electrode 14 are inserted into each other, which can be understood as both serving as receiving electrodes 15, the first embedded electrode 13 and the second embedded electrode 14 respectively have a conductive substrate 151 and an accommodation fixing structure 152 arranged on the conductive substrate 151, the accommodation fixing structure 152 on the first embedded electrode 13 can be inserted and fixed by the second embedded electrode 14, and the accommodation fixing structure 152 on the second embedded electrode 14 can be inserted and fixed by the first embedded electrode 13. The accommodation fixing structure 152 includes an accommodation cavity 1525 or a flexible structure 1522. For example, referring to FIG. 2 and FIG. 3, the accommodation fixing structure 152 includes a conductive side wall 1521, a flexible structure 1522, and a conductive sheet 1523. The conductive side wall 1521 is enclosed on the conductive substrate 151 to form a filling cavity 1526, and is electrically connected to the conductive substrate 151. The flexible structure 1522 is filled in the filling cavity 1526. The conductive sheet 1523 is covered on a side of the accommodation fixing structure 152 facing away from the conductive substrate 151, and the conductive sheet 1523 is electrically connected to the conductive side wall 1521. The conductive substrate 151, the conductive side wall 1521 and the conductive sheet 1523 are all metal materials. The material of the conductive substrate 151 can be the pad material used in the traditional drive bonding backplane, such as one or a combination of copper, nickel, gold, silver and other metals, with a thickness in a range of about 1 to 2 micrometers. The conductive substrate 151, the conductive side wall 1521 and the conductive sheet 1523 can be made of the same metal material or different metal materials. When the conductive substrate 151, the conductive side wall 1521 and the conductive sheet 1523 are made of the same metal material, the thermal expansion coefficients of the three are the same, and the bonding effect is better. The flexible structure 1522 may be made of a soft material such as silicone, resin, or photoresist, and the hardness of the flexible structure 1522 may be 40 to 80 Shore A hardness (HA). The thickness of the conductive side wall 1521 and the flexible structure 1522 is about 1 to 2 micrometers, and the thickness of the conductive sheet 1523 is less than 1 micrometer, for example, between 300 and 500 nanometers, which makes it easy to be inserted and electrically connected by the insertion electrode 16. In an embodiment, the insertion electrode 16 may include, for example, a solder layer 161 and a conductive spike 162 disposed on one side of the solder layer 161. The conductive spike 162 may penetrate through the conductive sheet 1523 and penetrate into the flexible structure 1522, so that the insertion electrode 16 is electrically connected to the receiving electrode 15 through the conductive sheet 1523. Here, the combination of the solder layer 161 and the conductive spike 162 serves as a specific implementation of the insertion structure of the embodiment of the disclosure. The diameter of the conductive spike 162 is less than 1 micrometer, such as between 500 nanometers and 1 micrometer, and the height is between 1 and 2 micrometers, so that the conductive spike 162 can better penetrate the conductive sheet 1523. The solder layer 161 can be made of conventional solder metals such as tin, nickel, copper, indium, bismuth or their alloys. For example, when the first embedded electrode 13 as illustrated FIG. 2 is used as the insertion electrode 16 (that is, when the insertion electrode 16 is provided on the microelectronic element 11), the solder layer 161 is provided on the P electrode and the N electrode of the micro-LED. On the contrary, for example, when the second embedded electrode 14 is used as the insertion electrode 16 as illustrated FIG. 3 (that is, the insertion electrode 16 is provided on the bonding substrate 12), the solder layer 161 is provided on the bonding substrate 12.

Specifically, the preparation process of the receiving electrode 15 provided in this embodiment may, for example, include the following steps. A bonding substrate 12 (or a microelectronic element 11) is provided, and at least one or more spare electrode positions on the bonding substrate 12 in addition to the conventional electrode positions are reserved. A conductive substrate is formed corresponding to each electrode position. A conductive side wall is formed on a side of the conductive substrate facing away from the bonding substrate 12 (or the microelectronic element 11), and a filling cavity is formed on each conductive substrate. For example, a flexible material layer (i.e., flexible structure, e.g., silica gel layer) is coated on a side of the bonding substrate 12 (or the microelectronic element 11) adjacent to the conductive substrate by means of spin coating. The unwanted parts of the flexible material layer (i.e., parts other than each filling cavity) are etched. A conductive sheet is formed on the side of the flexible material layer facing away from the bonding substrate 12. The formation process of the conductive substrate, the conductive side wall and the conductive sheet can adopt an evaporation process, and the growth can be carried out only at the position needing to be grown through a mask process. The step of removing the excess flexible material may also be performed after the conductive sheet is formed.

Referring to FIG. 4 illustrates a schematic flowchart of a repair method for the bonding assembly 10 illustrated FIG. 2. Only two sets of second embedded electrodes 14 on the bonding substrate 12 are illustrated, one of which is spare electrodes, but this embodiment is not limited thereto. In the step (a) in FIG. 4, the microelectronic element 11 and the bonding substrate 12 in the bonding assembly 10 are provided, respectively, with the first embedded electrode 13 on the microelectronic element 11 as the insertion electrode 16 and the second embedded electrode 14 on the bonding substrate 12 as the receiving electrode 15. The microelectronic element 11 is bonded to the left set of electrodes of the bonding substrate 12, and the microelectronic element 11 is pressed down, so that the conductive spike 162 on the insertion electrode 16 pierce through the conductive sheet 1523 on the receiving electrode 15 and pierce into the flexible structure 1522, resulting in the structure after the first bonding as illustrated step (b) in FIG. 4. At this time, the conductive spike 162 on the insertion electrode 16 is clamped and fixed by the conductive sheet 1523 and the flexible structure 1522, and the conductive spike 162 and the solder layer 161 are electrically connected to the conductive sheet 1523. After the first transfer is completed, the bonding substrate 12 is energized to drive the microelectronic element 11. If the microelectronic element 11 emits light, the bonding is normal. If the microelectronic element 11 does not emit light, the bonding is abnormal and needs to be repaired. In the step (c) in FIG. 4, the microelectronic element 11 with the first abnormal bonding is removed. Prior to the step (c) in FIG. 4, the right set of receiving electrodes 15 (i.e., the spare electrodes) has not been subjected to the bonding process, and a new microelectronic element 11 may be transferred to the set of spare electrodes in the step (d). The conductive spike 162 on the insertion electrode 16 of the new microelectronic element 11 pierces the conductive sheet 1523 on the receiving electrode 15 and pierces into the flexible structure 1522, resulting in the repaired structure as illustrated the step (d) of FIG. 4. At this time, the conductive spike 162 on the insertion electrode 16 is clamped and fixed by the conductive sheet 1523 and the flexible structure 1522, and the conductive spike 162 and the solder layer 161 are electrically connected to the conductive sheet 1523. In this situation, the bonding of the spare electrodes can be tested to determine whether the bonding is normal. If the bonding is abnormal, the above repair steps can be continued. If the bonding is normal, the bonding substrate 12 can be heated as a whole so that the solder layer 161 is melted to realize the soldering of all the microelectronic elements 11 and the bonding substrate 12 on the entire panel. In this way, in the whole transfer repair process, the heating welding can be performed only after the last transfer, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Second Embodiment

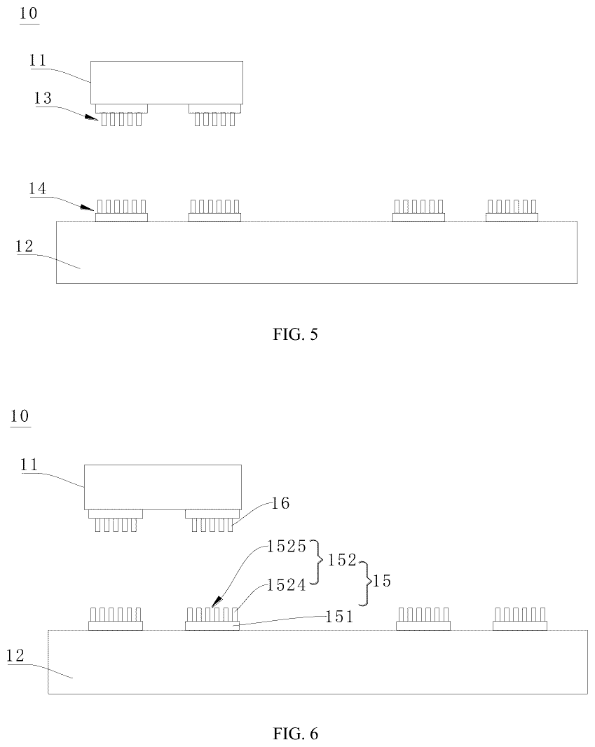

Referring to FIG. 5, the second embodiment of the disclosure provides another bonding assembly 10 including a microelectronic element 11, a bonding substrate 12, a first embedded electrode 13 (i.e., chip electrode) arranged on a side of the microelectronic element 11 and electrically connected to the microelectronic element 11, and a second embedded electrode 14 (i.e., substrate electrode) arranged on a side of the bonding substrate 12 and electrically connected to the bonding substrate 12. In this embodiment, the combination of the microelectronic element 11 and the first embedded electrode 13 is a specific implementation of the microelectronic component, and the bonding substrate 12 and the second embedded electrode 14 are a specific implementation of the bonding backplane. The microelectronic component and the bonding backplane can be embedded with each other through the first embedded electrode 13 and the second embedded electrode 14, so that the first embedded electrode 13 and the second embedded electrode 14 are bonded together, so as to realize the electrical connection between the microelectronic element 11 and the bonding substrate 12. The first embedded electrode 13 and the second embedded electrode 14 can be embedded with each other, so that the microelectronic element 11 can be bonded to the bonding substrate 12. At least one of the first embedded electrode 13 and the second embedded electrode 14 acts as the receiving electrode 15 and the other of the first embedded electrode 13 and the second embedded electrode 14 acts as the insertion electrode 16. The receiving electrode 15 includes a conductive substrate 151 and an accommodation fixing structure 152 arranged on the conductive substrate 151. The accommodation fixing structure 152 can be inserted into the insertion electrode 16 and fixed the insertion electrode 16. The microelectronic element 11, for example, is a micro light-emitting device, specifically, for example, a micro-LED chip. As illustrated FIG. 5, a flip-chip micro-LED chip has a P-type semiconductor layer and an N-type semiconductor layer, and the P-type semiconductor layer and the N-type semiconductor layer are each provided with a first embedded electrode 13. The corresponding bonding substrate 12, for example, is a micro-LED driving circuit board, and the bonding substrate 12 is provided with two second embedded electrodes 14 corresponding to one micro-LED chip. The bonding substrate 12 is provided with multiple second embedded electrodes which can bond multiple micro-LED chips. Of course, FIG. 5 only illustrates the structure of the flip-chip micro-LED chip for the microelectronic element 11. The microelectronic element 11 can also be, for example, a vertical micro-LED chip. For example, a first embedded electrode 13 is provided on a P-type semiconductor layer of the vertical micro-LED chip, a second embedded electrode 14 is provided on the bonding substrate 12 corresponding to a bonding position of the micro-LED chip. For example, the second embedded electrode 14 on the bonding substrate 12 is used as the receiving electrode 15, and the first embedded electrode 13 on the microelectronic element 11 is used as the insertion electrode 16. On the contrary, in some embodiments, the first embedded electrode 13 can be used as the receiving electrode 15 and the second embedded electrode 14 on the bonding substrate 12 can be used as the insertion electrode 16. Alternatively, in the structure of the bonding assembly 10 as illustrated FIG. 6, the first embedded electrode 13 and the second embedded electrode 14 can be inserted into each other, which can be understood as both serving as receiving electrodes 15, the first embedded electrode 13 and the second embedded electrode 14 respectively have a conductive substrate 151 and an accommodation fixing structure 152 arranged on the conductive substrate 151, the accommodation fixing structure 152 on the first embedded electrode 13 can be inserted and fixed by the second embedded electrode 14, and the accommodation fixing structure 152 on the second embedded electrode 14 can be inserted and fixed by the first embedded electrode 13. The accommodation fixing structure 152 includes an accommodation cavity 1525 or a flexible structure 1522.

In this embodiment, the accommodation fixing structure 152 includes, for example, multiple nanorods 1524, which are arranged spaced apart from each other, and gaps between the multiple nanorods 1524 form an accommodation cavity 1525 to accommodate the insertion electrode 16. Among the multiple nanorods 1524, the height of each nanorod 1524 is, for example, 2-3 micrometers (the overall thickness of the receiving electrode 15 is 3-4 micrometers), the width (or diameter) of each nanorod 1524 is, for example, between 200-500 nanometers, and the gap between two adjacent nanorods 1524 is basically equal to the width of each nanorod 1524. That is, the gap between two adjacent nanorods 1524 is about 200-500 nanometers. In some embodiments, the structures of the first embedded electrode 13 and the second embedded electrode 14 are the same, a gap distance between two adjacent nanorods in the first embedded electrode 13 is equal to the width of each nanorod 1524 on the second embedded electrode 14. A gap distance between two adjacent nanorods in the second embedded electrode 14 is equal to the width of each nanorod 1524 on the first embedded electrode 13 (as another specific implementation of the insertion structure as this embodiment of the disclosure). In this situation, the multiple of nanorods of the first embedded electrode 13 and the second embedded electrode 14 can be fixed in contact with each other. Specifically, the multiple nanorods 1524 may be made of a metal material, such as copper, nickel, etc., the metal material has good ductility, so that the first embedded electrode 13 and the second embedded electrode 14 can be slightly deformed in the process of being inserted into each other to be better combined and not easy to be damaged. More specifically, the multiple nanorods on the first embedded electrode 13 and the second embedded electrode 14, for example, are made of the same metal. Alternatively, the nanorods on one of the first embedded electrode 13 and the second embedded electrode 14 may be made of weldable materials such as tin, nickel, copper, indium, bismuth or their alloy, and the nanorods on the other of the first embedded electrode 13 and the second embedded electrode 14 may be made of copper, nickel and other metals that can be mutually melted with the weldable material, so that the heating welding of the first embedded electrode 13 and the second embedded electrode 14 can be realized.

Specifically, the preparation process of receiving electrode 15 provided in this embodiment may, for example, include the following steps. A bonding substrate 12 (or a microelectronic element 11) is provided, and at least one or more spare electrode positions on the bonding substrate 12 in addition to the conventional electrode positions are reserved. A conductive substrate is formed corresponding to each electrode position. Multiple nanorods are formed on a side of the conductive substrate facing away from the bonding substrate 12 (or the microelectronic element 11). The formation process of the conductive substrate and the multiple nanorods can be evaporation plating or chemical plating. Alternatively, metal can be used to form a whole metal block at each electrode position, and then multiple nanorods can be formed on the metal block by etching and other processes. The above formation process is only illustrative, and this embodiment is not limited thereto.

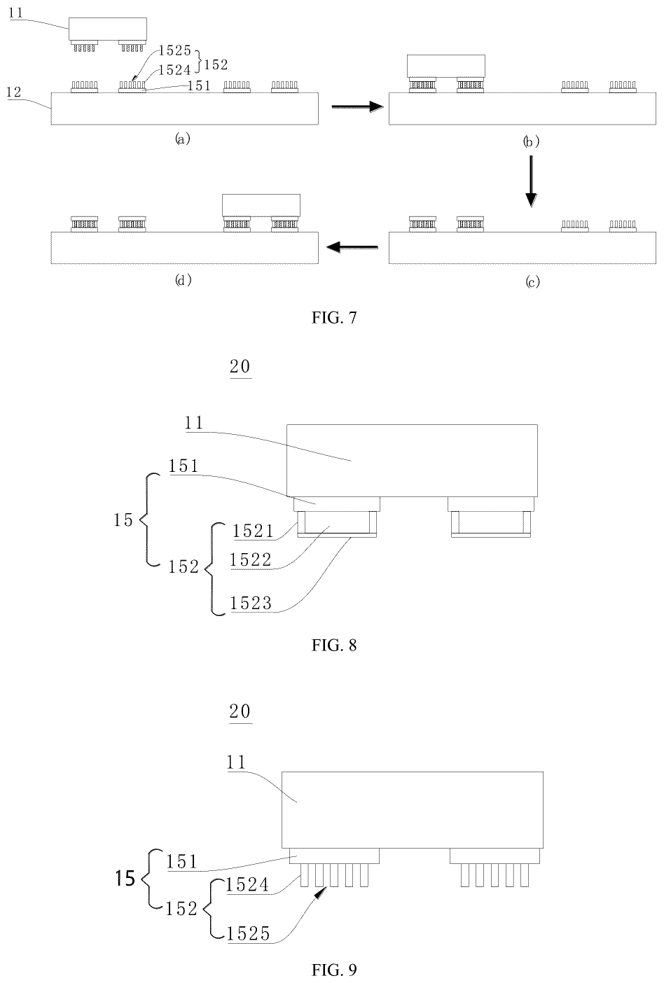

FIG. 7 illustrates a schematic flowchart of a repair method for the bonding assembly 10 illustrated FIG. 6. Only two sets of second embedded electrodes 14 on the bonding substrate 12 are illustrated, one of which is spare electrodes, but this embodiment is not limited thereto. In the step (a) in FIG. 7, the microelectronic element 11 and the bonding substrate 12 in the bonding assembly 10 are provided, respectively. The first embedded electrode 13 on the microelectronic element 11 and the second embedded electrode 14 on the bonding substrate 12 both have accommodation fixing structures 152. That is, the first embedded electrode 13 and the second embedded electrode 14 serve as the receiving electrode 15 and the insertion electrode 16 for each other. In the step (a) in FIG. 7, the microelectronic element 11 is bonded to the left set of electrodes of the bonding substrate 12, and the microclectronic element 11 is pressed down, so that multiple nanorods 1524 of the first embedded electrode 13 and the second embedded electrode 14 are inserted into each other to obtain the structure after the first transfer as illustrated in the step (b) of FIG. 7. At this time, due to the “burr” shapes of multiple nanorods 1524, the first embedded electrode 13 and the second embedded electrode 14 can be closely combined with each other and achieve electrical connection. After the first transfer is completed, the bonding substrate 12 is energized to drive the microelectronic element 11. If the microelectronic element 11 emits light, the bonding is normal. If the microelectronic element 11 does not emit light, the bonding is abnormal and needs to be repaired. In the step (c) in FIG. 7, the microelectronic element 11 with the first abnormal bonding is removed. Prior to the step (c) in FIG. 7, the right set of spare electrodes has not been subjected to the bonding process, and in the step (d) in FIG. 7, a new microelectronic element 11 can be transferred to the set of spare electrodes. The first embedded electrode 13 of the new microelectronic element 11 and the second embedded electrode 14 at the position of the spare electrodes are inserted with each other to obtain the repaired structure as illustrated step (d) of FIG. 7. In this situation, the bonding of the spare electrodes can be tested to determine whether the bonding is normal. If the bonding is abnormal, the above repair steps can be continued. If the bonding is normal, due to the “burr” shapes of nanorods 1524, the microclectronic element 11 can be stably bonded to the bonding substrate 12, and the bonding is completed without heating welding, which can reduce the influence of heating welding. Of course, if necessary, the nanorods 1524 of one of the first embedded electrode 13 and the second embedded electrode 14 may be selected as a welding material, and the nanorods 1524 of the other of the first embedded electrode 13 and the second embedded electrode 14 may be selected as a metal material that can be mutually melted with the welding material, then all the microelectronic elements 11 on the entire bonding substrate 12 can be heated welding after the last transfer. In this way, in the whole transfer repair process, the heating welding can be performed only after the last transfer, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Third Embodiment

As illustrated FIG. 8, the third embodiment of the disclosure provides a microelectronic component 20 including a microelectronic element 11 and a receiving electrode 15. The receiving electrode 15 is electrically connected to the microelectronic element 11. The receiving electrode 15 has a conductive substrate 151 and an accommodation fixing structure 152 arranged on the conductive substrate 151. The accommodation fixing structure 152 may be inserted by an insertion electrode on a bonding substrate and fixed the insertion electrode, so that the microelectronic element 11 can be bonded to the bonding substrate.

The microelectronic element 11, for example, is a micro light-emitting device, specifically, for example, a micro-LED chip. As illustrated FIG. 8, a flip-chip micro-LED chip has a P-type semiconductor layer and an N-type semiconductor layer, and the P-type semiconductor layer and the N-type semiconductor layer are each provided with a receiving electrode 15. The conductive substrate 151, for example, is the P electrode or N electrode of the traditional micro-LED chip, and has a thickness ranging from about 1 to 2 micrometers. Of course, FIG. 8 only illustrates the structure of the flip-chip micro-LED chip for the microelectronic element 11, the microelectronic element 11 can also be, for example, a vertical micro-LED chip, and the receiving electrode 15 is provided on a P-type semiconductor layer of the vertical micro-LED chip. The accommodation fixing structure 152 includes an accommodation cavity 1525 or a flexible structure 1522. Referring to FIG. 8, the accommodation fixing structure 152 includes a conductive side wall 1521, a flexible structure 1522, and a conductive sheet 1523. The conductive side wall 1521 is enclosed on the conductive substrate 151 to form a filling cavity 1526 and is electrically connected to the conductive substrate 151. The flexible structure 1522 is filled in the filling cavity 1526. The conductive sheet 1523 is covered on a side of the accommodation fixing structure 152 facing away from the conductive substrate 151, and the conductive sheet 1523 is electrically connected to the conductive side wall 1521. The conductive substrate 151, the conductive side wall 1521 and the conductive sheet 1523 are all made of metal materials, such as one or a combination of copper, nickel, gold, silver and other metals. The conductive substrate 151, the conductive side wall 1521 and the conductive sheet 1523 can be made of the same metal material or different metal materials. When the conductive substrate 151, the conductive side wall 1521 and the conductive sheet 1523 are made of the same metal material, the thermal expansion coefficients of the three are the same, and the bonding effect is better. The flexible structure 1522 may be made of a soft material such as silicone, resin, or photoresist, and the hardness of the flexible structure 1522 can be 40 to 80 HA. The thickness of the conductive side wall 1521 and the flexible structure 1522 is about 1 to 2 micrometers, and the thickness of the conductive sheet 1523 is less than 1 micrometer, for example, between 300 and 500 nanometers, which makes it easy to be inserted and electrically connected by the insertion electrode on the bonding substrate. The combination is easier when the insertion electrode on the bonding substrate is set into a spiky shape. The microelectronic component 20 provided in this embodiment can realize the repair method similar to that described in the first embodiment above. In the whole transfer repair process, the heating welding can be performed only after the last transfer, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Fourth Embodiment

As illustrated FIG. 9, the fourth embodiment of the disclosure provides a microelectronic component 20 including a microelectronic element 11 and a receiving electrode 15. The receiving electrode 15 is electrically connected to the microelectronic element 11. The receiving electrode 15 has a conductive substrate 151 and an accommodation fixing structure 152 arranged on the conductive substrate 151. The accommodation fixing structure 152 may be inserted by an insertion electrode on a bonding substrate and fixed the insertion electrode, so that the microelectronic element 11 can be bonded to the bonding substrate.

The microelectronic element 11, for example, is a micro light-emitting device, specifically, for example, a micro-LED chip. As illustrated FIG. 9, a flip-chip micro-LED chip has a P-type semiconductor layer and an N-type semiconductor layer, and the P-type semiconductor layer and the N-type semiconductor layer are each provided with a receiving electrode 15. The conductive substrate 151, for example, is the P electrode or N electrode of the traditional micro-LED chip, and has a thickness ranging from about 1 to 2 micrometers. Of course, FIG. 9 only illustrates the structure of the flip-chip micro-LED chip for the microelectronic element 11, the microelectronic element 11 can also be, for example, a vertical micro-LED chip, and the receiving electrode 15 is provided on a P-type semiconductor layer of the vertical micro-LED chip.

Referring to FIG. 9, the accommodation fixing structure 152 of this embodiment, for example, includes multiple nanorods 1524 arranged on a side of the conductive substrate 151 facing away from the microelectronic element 11. The nanorods 1524 are arranged spaced apart from each other, and gaps between the multiple nanorods 1524 form an accommodation cavity 1525 to accommodate the insertion electrode on the bonding substrate. Among the multiple nanorods 1524, the height of each nanorod 1524 is, for example, 2-3 micrometers (the overall thickness of the receiving electrode 15 is 3-4 micrometers), the width (or diameter) of each nanorod 1524 is, for example, between 200-500 nanometers, and the gap between two adjacent nanorods 1524 is basically equal to the width of each nanorod 1524. That is, the gap between two adjacent nanorods 1524 is about 200-500 nanometers. Specifically, the multiple nanorods 1524 may be made of metal materials, such as copper, nickel, etc., the metal material has good ductility, so that the multiple nanorods 1524 can be slightly deformed to better combined and not easy to be damaged during the bonding process. The structure that the microelectronic component 20 provided in this embodiment is provided with multiple nanorods 1524 can be matched with the structure that the insertion electrode on the bonding substrate is provided with the same structure as the receiving electrode 15 in this embodiment, so that the stable bonding can be realized through the mutual insertion of the nanorods, and the repair solution similar to the second embodiment is realized. In this embodiment, the multiple nanorods 1524 of the accommodation fixing structure 152 may be metal materials such as copper and nickel, or weldable materials such as tin, nickel, copper, indium, bismuth, or their alloys. The non-heating welding bonding or the heating welding bonding can be realized by matching with the arrangement of the insertion electrode on the bonding substrate, and the arrangement is carried out according to actual requirements, and the embodiment is not limited thereto. Using the structure of the microelectronic component 20 provided in this embodiment, in the whole transfer repair process, the heating welding can be performed only after the last transfer, or no welding is required, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Fifth Embodiment

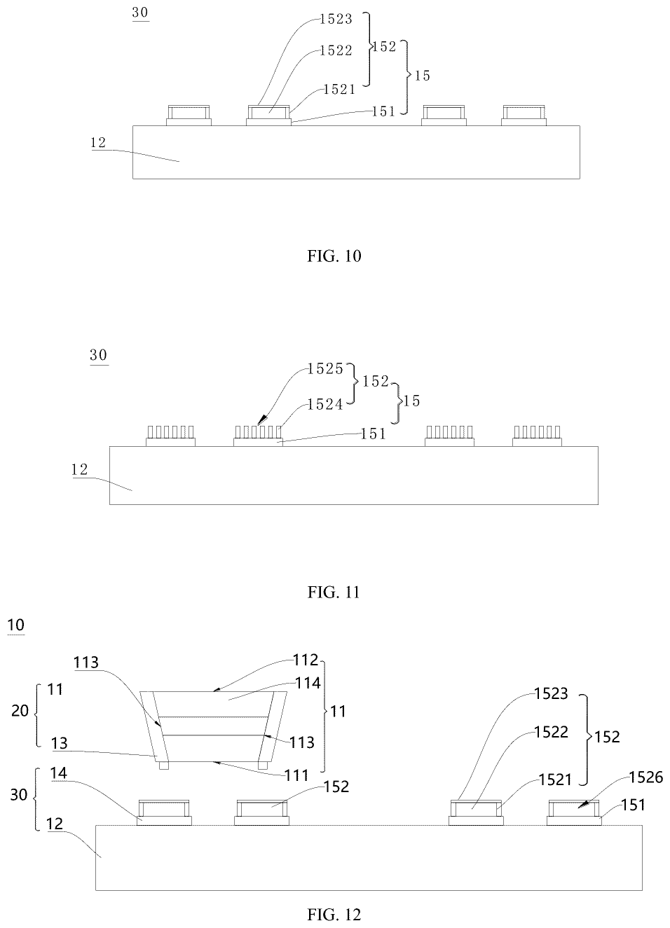

As illustrated FIG. 10, the fifth embodiment of the disclosure provides a bonding backplane 30 including a bonding substrate 12 and a receiving electrode 15. The receiving electrode 15 is electrically connected to the microelectronic element 11. The receiving electrode 15 has a conductive substrate 151 and an accommodation fixing structure 152 arranged on the conductive substrate 151. The accommodation fixing structure 152 can be inserted and fixed by an insertion electrode 16 on a microelectronic element, so that the microelectronic element can be bonded to the bonding substrate 12.

The bonding substrate 12, for example, is a micro-LED driving circuit board, when the bonding substrate 12 is used to bond a flip-chip micro-LED chip, the bonding substrate 12 is provided with two receiving electrodes 15 corresponding to one micro-LED chip. The bonding substrate 12 is provided with multiple receiving electrodes for bonding multiple micro-LED chips. When the bonding substrate 12 is used to bond a vertical micro-LED chip, the bonding substrate 12 is provided with one receiving electrode 15 corresponding to one micro-LED bonding position. As illustrated FIG. 10, only two sets of receiving electrodes 15 on the bonding substrate 12 are shown for bonding two micro-LEDs, one of which is, for example, spare electrodes for the other set. The conductive substrate 151, for example, can be the bonding pad material on the micro-LED driving circuit board, such as one or a combination of copper, nickel, gold, silver and other metals, with a thickness in a range of about 1 to 2 micrometers. The accommodation fixing structure 152 includes an accommodation cavity 1525 or a flexible structure 1522. For example, referring to FIG. 10, the accommodation fixing structure 152 includes a conductive side wall 1521, a flexible structure 1522, and a conductive sheet 1523. The conductive side wall 1521 is enclosed on the conductive substrate 151 to form a filling cavity 1526 and is electrically connected to the conductive substrate 151. The flexible structure 1522 is filled in the filling cavity 1526. The conductive sheet 1523 is covered on a side of the accommodation fixing structure 152 facing away from the conductive substrate 151, and the conductive sheet 1523 is electrically connected to the conductive side wall 1521. The conductive substrate 151, the conductive side wall 1521 and the conductive sheet 1523 are all made of metal materials, such as one or a combination of copper, nickel, gold, silver and other metals. The conductive substrate 151, the conductive side wall 1521 and the conductive sheet 1523 can be made of the same metal material or different metal materials. When the conductive substrate 151, the conductive side wall 1521 and the conductive sheet 1523 are made of the same metal material, the thermal expansion coefficients of the three are the same, and the bonding effect is better. The flexible structure 1522 may be made of a soft material such as silicone, resin, or photoresist, and the hardness of the flexible structure 1522 may be 40 to 80 HA. The thickness of the conductive side wall 1521 and the flexible structure 1522 is about 1 to 2 micrometers, and the thickness of the conductive sheet 1523 is less than 1 micrometer, for example, between 300 and 500 nanometers, which makes it easy to be inserted and electrically connected by the insertion electrode on the bonding substrate. The combination is simpler when the insertion electrode on the microelectronic element is set into a spiky shape. The bonding backplane 30 provided in this embodiment can realize the repair method similar to that described in the first embodiment above. In the whole transfer repair process, the heating welding can be performed only after the last transfer, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Sixth Embodiment

As illustrated FIG. 11, the sixth embodiment of the disclosure provides a bonding backplane 30 including a bonding substrate 12 and a receiving electrode 15. The receiving electrode 15 is electrically connected to the microelectronic element 11. The receiving electrode 15 has a conductive substrate 151 and an accommodation fixing structure 152 arranged on the conductive substrate 151. The accommodation fixing structure 152 can be inserted and fixed by an insertion electrode 16 on a microelectronic element, so that the microelectronic element can be bonded to the bonding substrate 12.

The bonding substrate 12, for example, is a micro-LED driving circuit board, when the bonding substrate 12 is used to bond a flip-chip micro-LED chip, the bonding substrate 12 is provided with two receiving electrodes 15 corresponding to one micro-LED chip. The bonding substrate 12 is provided with multiple receiving electrodes for bonding multiple micro-LED chips. When the bonding substrate 12 is used to bond a vertical micro-LED chip, the bonding substrate 12 is provided with one receiving electrode 15 corresponding to one micro-LED bonding position. As illustrated FIG. 11, only two sets of receiving electrodes 15 on the bonding substrate 12 are shown for bonding two micro-LEDs, one of which is, for example, spare electrodes for the other set. The conductive substrate 151, for example, can be the bonding pad material on the micro-LED driving circuit board, such as one or a combination of copper, nickel, gold, silver and other metals, with a thickness in a range of about 1 to 2 micrometers.

Referring to FIG. 11, the accommodation fixing structure 152 of this embodiment, for example, includes multiple nanorods 1524 arranged on a side of the conductive substrate 151 facing away from the microelectronic element 11. The nanorods 1524 are arranged spaced apart from each other, and gaps between the multiple nanorods 1524 form an accommodation cavity 1525 to accommodate the insertion electrode on the microelectronic element. Among the multiple nanorods 1524, the height of each nanorod 1524 is, for example, 2-3 micrometers (the overall thickness of the receiving electrode 15 is 3-4 micrometers), the width (or diameter) of each nanorod 1524 is, for example, between 200-500 nanometers, and the gap between two adjacent nanorods 1524 is basically equal to the width of each nanorod 1524. That is, the gap between two adjacent nanorods 1524 is about 200-500 nanometers. Specifically, the multiple nanorods 1524 may be made of metal materials, such as copper, nickel, etc., the metal material has good ductility, so that the multiple nanorods 1524 can be slightly deformed to better combined and not easy to be damaged during the bonding process. The structure that the bonding backplane 30 provided in this embodiment is provided with multiple nanorods 1524 can be matched with the structure that the insertion electrode on the microelectronic element is provided with the same structure as the receiving electrode 15 in this embodiment, so that the stable bonding can be realized through the mutual insertion of the nanorods, and the repair solution similar to the second embodiment is realized. In this embodiment, the multiple nanorods 1524 of the accommodation fixing structure 152 may be metal materials such as copper and nickel, or weldable materials such as tin, nickel, copper, indium, bismuth, or their alloys. The non-heating welding bonding or the heating welding bonding can be realized by matching with the arrangement of the insertion electrode on the bonding substrate, and the arrangement is carried out according to actual requirements, and the embodiment is not limited thereto. Using the structure of the bonding backplane 30 provided in this embodiment, in the whole transfer repair process, the heating welding can be performed only after the last transfer, or no welding is required, the single-point heating welding of the above-mentioned related art is not needed, and the quality of the surrounding solder joints is not affected. In addition, in the repair process, only the micro-LED at the bad point position needs to be removed, and the process of removing the adhesive layer and supplementing the adhesive material in the related art is not needed, so that the repairing process is simpler and more feasible.

### Seventh Embodiment

Referring to FIG. 12, the seventh embodiment of the disclosure provides a bonding assembly 10, including a bonding backplane 30 and a microelectronic component 20. The bonding backplane 30 includes a bonding substrate 12 and a substrate electrode 14, and the substrate electrode 14 is arranged on a side of the bonding substrate 12 and is electrically connected to the bonding substrate 12. The microelectronic component 20 includes a microelectronic element 11 and a chip electrode 13, having a first surface 111 and a second surface 112 opposite to each other along a first direction, and side surfaces 113 adjacent to a first surface 111 and a second surface 112. The microelectronic element 11 includes multiple semiconductor layers 114 stacked along the first direction. The chip electrode 13 is electrically connected to the microelectronic element 11 and is at least partially arranged on the side surface 113 of the microelectronic element 11. The bonding backplane 30 and the microelectronic component 20 can be embedded with each other, so that the substrate electrode 14 and the chip electrode 13 can be bonded to each other, and at least one of the microelectronic component 20 and the bonding backplane 30 forms a receiving structure and the other of the microelectronic component 20 and the bonding backplane 30 forms an insertion structure. The receiving structure includes an accommodation fixing structure 152, the accommodation fixing structure 152 can be inserted and fixed by the insertion structure.

The microelectronic element 11, for example, is a micro light-emitting device, specifically, such as a micro-LED chip. The microelectronic element 11 contains multiple semiconductor layers 114, such as N-type semiconductor layer, multiple quantum well layer (MQW layer), and P-type semiconductor layer, etc. The N-type semiconductor layer, the MQW layer and the P-type semiconductor layer can be arranged in multiple layers. The first direction is the stacking direction of multiple semiconductor layers 114. The first direction is a longitudinal direction illustrated FIG. 12. Of course, in addition to the multiple semiconductor layers 114, the microelectronic element 11, for example, can further include a reflection layer, an ohmic contact layer, an insulation layer, etc., the layers contained in the microelectronic element 11 can be set up with reference to the structure of the traditional micro-LED chip. The first surface 111 and the second surface 112 are two surfaces of the microelectronic element 11 opposite each other in the stacking direction, and can also be referred to as a bottom surface and a top surface of the microelectronic element 11. The chip electrode 13 may include an N electrode connected to an N-type semiconductor layer and a P electrode connected to a P-type semiconductor layer, and the chip electrode 13 may be at least partially disposed on the side surface 113. The N electrode may be fully disposed on the side surface 113, the P electrode may be fully disposed on the first surface 111, or both the N electrode and the P electrode may be fully or partially disposed on the side surface 113. For example, the N electrode and the P electrode are arranged on opposite or adjacent side surfaces 113, which can increase the distance between the N electrode and the P electrode and reduce the mutual interference between the N electrode and the P electrode.

The corresponding bonding substrate 12, for example, is a micro-LED driving circuit board, and two substrate electrodes 14 are provided on the bonding substrate 12 corresponding to a micro-LED chip position. The bonding substrate 12 is provided with multiple substrate electrodes 14 that can bond multiple micro-LED chips.

At least one of the microelectronic component 20 and the bonding backplane 30 forms a receiving structure, and the other of the microelectronic component 20 and the bonding backplane 30 forms an insertion structure. For example, the receiving structure may be formed on the microelectronic component 20 and the insertion structure may be formed on the bonding backplane 30. Alternatively, the insertion structure is formed on the microelectronic component 20, and the receiving structure is formed on the bonding backplane 30. Alternatively, the microelectronic component 20 and the bonding backplane 30 both form an insertion structure and both form a receiving structure. The receiving structure or the insertion structure may be formed by the microelectronic element 11 or the bonding substrate 12 itself, or may be formed on the chip electrode 13 or the substrate electrode 14. When formed on the chip electrode 13, the receiving structure or the insertion structure may be formed on only one of the N electrode and the P electrode, or the receiving structure or the insertion structure may be formed on both the N electrode and the P electrode, or a receiving structure may be formed on one of the N electrode and the P electrode and an insertion structure may be formed on the other of the N electrode and the P electrode. The same applies to the case of forming on the substrate electrode 14, which is not repeatedly described here.

In this embodiment, the microelectronic component 20 and the bonding backplane 30 are arranged to be embedded with each other, so that the bonding of the chip electrode 13 and the substrate electrode 14 can be realized in the form of insertion, and the method of heating welding can be avoided in the bonding or repair process. Alternatively, after the bonding, the test is performed first, and after the test, the bonding of the microelectronic component 20 is performed on the pixel to be repaired, and after the repair is completed, all the microelectronic components 20 bound on the binding backplane 30 can be welded together, so that the influence on the adjacent solder joints can be avoided. In addition. there is no need to glue in the repair process, so that the repairing difficulty can be reduced.

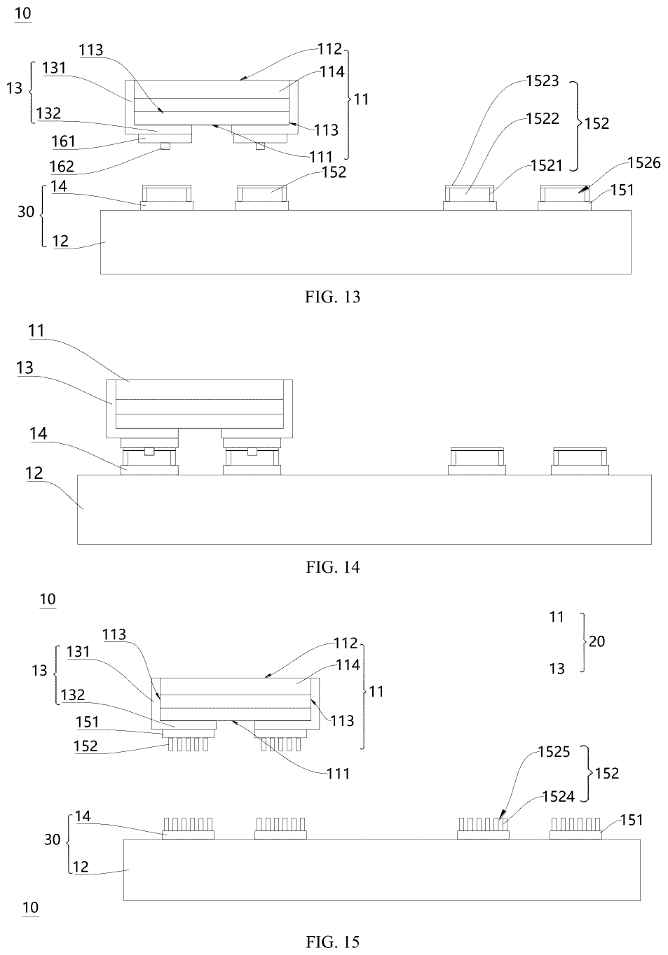

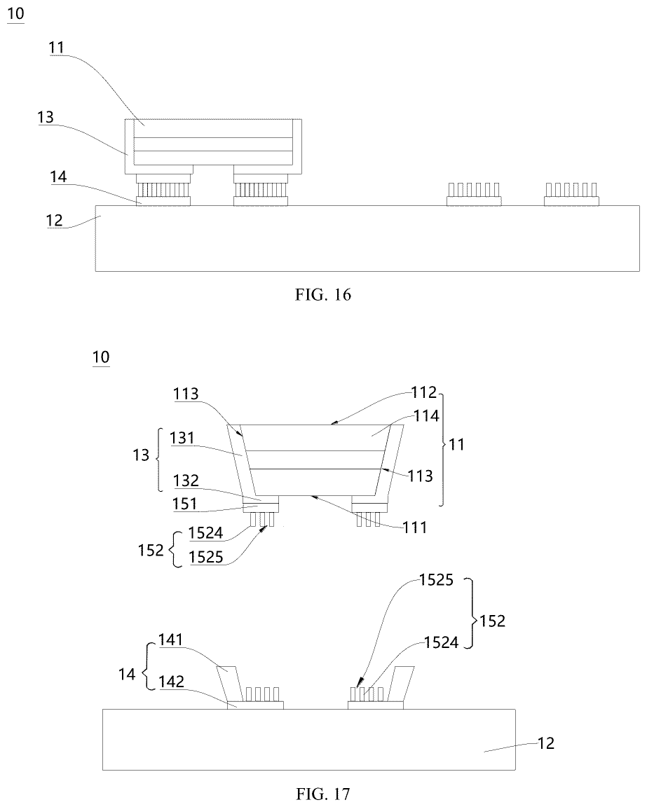

In some embodiments, a receiving structure is formed on at least one of the substrate electrode 14 and the chip electrode 13, and an insertion structure is formed on the other of the substrate electrode 14 and the chip electrode 13. Referring to FIG. 12, FIG. 13 and FIG. 14, the receiving structure is formed on the substrate electrode 14, and the insertion structure is formed on the chip electrode 13. Referring to FIG. 15 and FIG. 16, the receiving structure is formed on both the substrate electrode 14 and the chip electrode 13, and the insertion structure is also formed on both the substrate electrode 14 and the chip electrode 13.

Specifically, the receiving structure includes a conductive substrate 151 and an accommodation fixing structure 152 arranged on the conductive substrate 151. The accommodation fixing structure 152 includes an accommodation cavity 1525 or a flexible structure 1522.

Referring to FIG. 12 and FIG. 13, the accommodation fixing structure 152 includes a conductive side wall 1521, a flexible structure 1522 and a conductive sheet 1523. The conductive side wall 1521 is enclosed on the conductive substrate 151 to form a filling cavity 1526, and the conductive side wall 1521 is electrically connected to the conductive substrate 151. The flexible structure 1522 is filled in the filling cavity 1526, the conductive sheet 1523 is covered on the side of the flexible structure 1522 facing away from the conductive substrate 151, and the conductive sheet 1523 is electrically connected to the conductive side wall 1521.

The conductive substrate 151, the conductive side wall 1521 and the conductive sheet 1523 are all metal materials. The material of the conductive substrate 151 can be the pad material used in the traditional drive bonding backplane, such as one or a combination of copper, nickel, gold, silver and other metals, with a thickness range of about 1 to 2 micrometers. The conductive substrate 151, the conductive side wall 1521 and the conductive sheet 1523 can be made of the same metal material or different metal materials. When the conductive substrate 151, the conductive side wall 1521 and the conductive sheet 1523 are made of the same metal material, the thermal expansion coefficients of the three are the same, and the bonding effect is better. An orthographic shape of the filling cavity 1526 on the conductive substrate 151 can be circular, rectangular, etc. The flexible structure 1522 may be made of a soft material such as silicone, resin, or photoresist, and the hardness of the flexible structure 1522 may be 40 to 80 HA. The thickness of the conductive side wall 1521 and the flexible structure 1522 is about 1 to 2 micrometers, and the thickness of the conductive sheet 1523 is less than 1 micrometer, for example, between 300 and 500 nanometers, which makes it easy to be inserted and electrically connected by the insertion structure. In some embodiments, referring to FIG. 13, the insertion structure may, for example, include a solder layer 161 and a conductive spike 162 arranged on a side of the solder layer 161. The conductive spike 162 may penetrate through the conductive sheet 1523 and penetrate into the flexible structure 1522, so that the insertion structure is electrically connected to the receiving structure through the conductive sheet 1523. The diameter of the conductive spike 162 is less than 1 micrometer, such as between 500 nanometers and 1 micrometer, and the height is between 1 and 2 micrometers, so that the conductive spike 162 can better penetrate the conductive sheet 1523. The solder layer 161 can be made of conventional solder metals such as tin, nickel, copper, indium, bismuth or their alloys. For example, when the insertion structure is formed on the chip electrode 13 as illustrated FIG. 13, the solder layer 161 is arranged, for example, on the P and N electrodes of the micro-LED. Alternatively, the insertion structure may be formed on the substrate electrode 14, then the solder layer 161 is arranged, for example, on the substrate electrode 14 of the bonding substrate 12.

In some embodiments, referring to FIGS. 15 and 16, the accommodation fixing structure 152 includes multiple nanorods 1524, the multiple nanorods 1524 are arranged spaced apart from each other, and gaps among the multiple nanorods 1524 form an accommodation cavity 1525.

Among the multiple nanorods 1524, the height of each nanorod 1524 is 2-3 micrometers, the width (or diameter) of each nanorod 1524 is 200-500 nanometers, and the gap between two adjacent nanorods 1524 is basically equal to the width of each nanorod 1524. That is, the gap between two adjacent nanorods 1524 is about 200-500 nanometers. Then, the gap distance between two adjacent nanorods on the chip electrode 13 is equal to the width of each nanorods 1524 on the substrate electrode 14. Referring to FIG. 16, the gap distance between two adjacent nanorods on the substrate electrode 14 is equal to the width of each nanorod 1524 on the chip electrode 13. In this situation, the multiple nanorods 1524 on the chip electrode 13 and the substrate electrode 14 can be fixed in contact with each other. The multiple nanorods 1524 on the chip electrode 13 as an insertion structure are inserted into the accommodation cavity 1525 on the substrate electrode 14, and the multiple nanorods 1524 on the substrate electrode 14 as an insertion structure are inserted into the accommodation cavity 1525 on the chip electrode 13. Specifically, the multiple nanorods 1524 may be made of a metal material, such as copper, nickel, etc., the metal material has good ductility, so that the chip electrode 13 and the substrate electrode 14 can be slightly deformed in the process of being inserted into each other to be better combined and not easy to be damaged. More specifically, the multiple nanorods 1524 on the chip electrode 13 and the substrate electrode 14, for example, are made of the same metal. Alternatively, the nanorods 1524 on one of the chip electrode 13 and the substrate electrode 14 may be made of weldable materials such as tin, nickel, copper, indium, bismuth or their alloy, and the nanorods on the other of the chip electrode 13 and the substrate electrode 14 may be made of copper, nickel and other metals that can be mutually melted with the weldable material, so that the heating welding of the chip electrode 13 and the substrate electrode 14 can be realized.

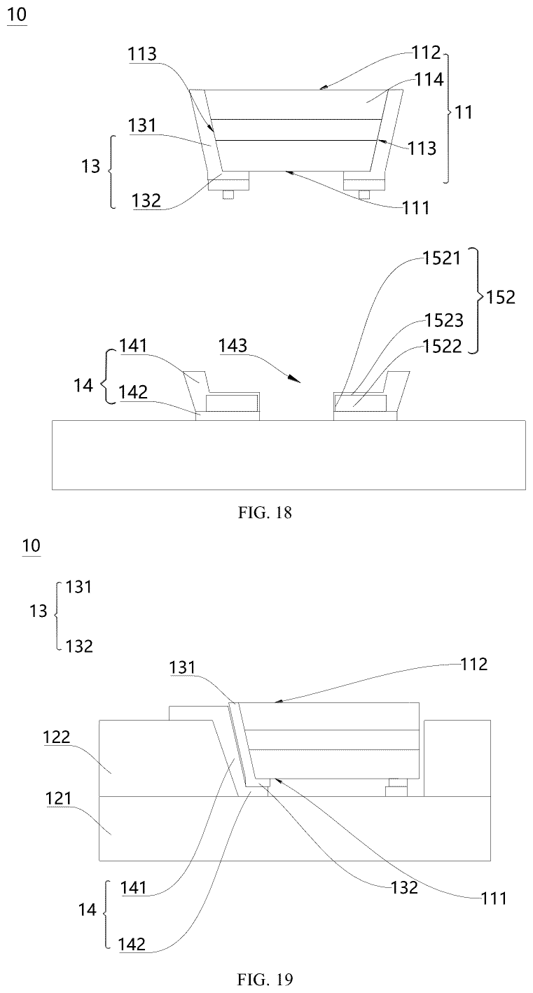

In some embodiments, the chip electrode 13 includes a chip electrode side part 131 located on the side surface 113 and a chip electrode bottom part 132 located on the first surface 111. The substrate electrode 14 includes a substrate electrode side part 141 and a substrate electrode bottom part 142, and the substrate electrode side part 141 extends from the substrate electrode bottom part 142 along a direction of the bonding substrate 12. The chip electrode bottom part 132 and the substrate electrode bottom part 142 are embedded with each other, and the chip electrode side part 131 is in contact with the substrate electrode side part 141 and limits the microelectronic component 20. As illustrated FIG. 17, when the multiple nanorods 1524 are utilized to form a structure that the multiple nanorods 1524 are inserted with each other, the multiple nanorods 1524 on the microelectronic component 20 are specifically formed on the chip electrode bottom part 132, and the multiple nanorods 1524 on the bonding backplane 30 are specifically formed on the substrate electrode bottom part 142. As illustrated FIG. 18, an accommodation fixing structure can also be formed on the substrate electrode bottom part 142 (which at this time may serve as the conductive substrate 151) by using a conductive side wall 1521, a flexible structure 1522 and a conductive sheet 1523, and a spike structure can be formed on the chip electrode bottom part 132. In this embodiment, the bonding can be realized by the chip electrode bottom part 132 and the substrate electrode bottom part 142 being embedded with each other. The contact area of the two electrodes can be increased through the contact of the substrate electrode side part 141 and the chip electrode side part 131, and the microelectronic component 20 can be limited, so that the bonding effect is better.

In some embodiments, multiple chip electrodes 13 corresponding to each microelectronic component 20 are respectively provided with multiple substrate electrodes 14, and the substrate electrode side parts 141 corresponding to the multiple substrate electrodes 14 of each microelectronic component 20 are enclosed together to form an accommodation groove 143, such that the microelectronic component 20 can be embedded in the accommodation groove 143. At this time, the accommodation groove 143 can also be used as the receiving structure to realize the fixation of the microelectronic component 20.

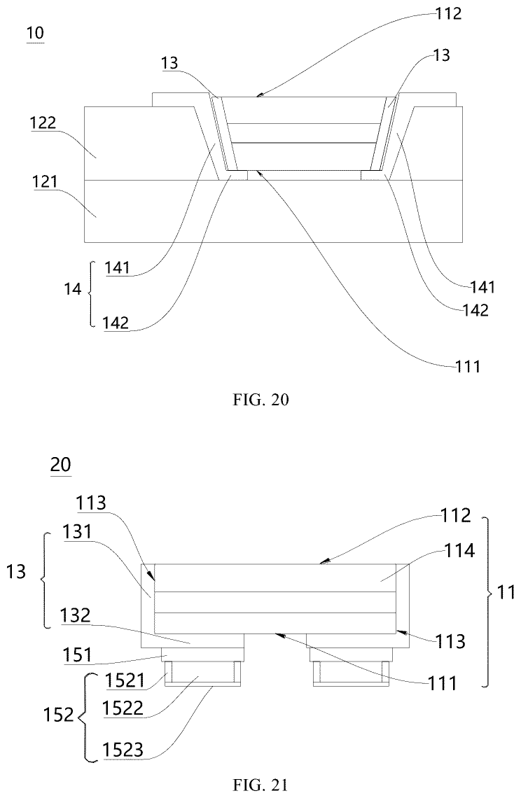

In some embodiments, referring to FIG. 19 and FIG. 20, a substrate groove 123 is formed on the bonding substrate 12, and the substrate electrode 14 is at least partially located in the substrate groove 123. The bonding substrate 12 serves as the receiving structure, the microelectronic element 11 and the chip electrode 13 together serve as the insertion structure, the substrate groove 123 serves as the accommodation fixing structure 152, and the microelectronic element 11 and the chip electrode 13 are inserted together into the substrate groove 123, so that the chip electrode 13 and the substrate electrode 14 are bonded to each other. Specifically, the bonding substrate 12 includes a driving circuit board 121 and a pixel definition layer 122 arranged on the driving circuit board 121. The driving circuit board 121 is provided with a driving circuit for driving the microelectronic component 20 to operate, the substrate electrode 14 is electrically connected to the driving circuit, and the substrate groove 123 is specifically formed on the pixel definition layer 122. By directly forming the substrate groove 123 on the bonding substrate 12, the structure is simpler while the bonding with embedment is realized.

In some embodiments, the chip electrode 13 includes a chip electrode side part 131 located on the side surface 113. The substrate electrode 14 includes a substrate electrode side part 141 covered on a side wall of the substrate groove 123 and in contact with the chip electrode side part 131. Referring to FIG. 19, if only one of the N electrode or the P electrode of the chip electrode 13 has the chip electrode side part 131, only the substrate electrode side part 141 may correspond. Referring to FIG. 20, if multiple electrodes in the chip electrode 13 have chip electrode side parts 131, the substrate electrode side parts 141 may be provided respectively corresponding to the two chip electrode side parts 131, or the substrate electrode side part 141 may be provided only for one chip electrode side part 131. In this embodiment, the bonding area of the chip electrode 13 and the substrate electrode 14 can be increased and the bonding effect and conduction effect can be enhanced by setting the substrate electrode side part 141 on the side of substrate groove 123.

In some embodiments, referring to FIG. 19, the chip electrode 13 further includes a chip electrode bottom part 132 connected to the chip electrode side part 131, and the chip electrode bottom part 132 is located on the first surface 111. The substrate electrode 14 further includes a substrate electrode bottom part 142 connected to the substrate electrode side part 141 and located at the bottom of the substrate groove 123. The substrate electrode bottom part 142 is located on the side of the chip electrode bottom part 132 facing away from the microelectronic element 11 and is in contact with the chip electrode bottom part 132.

### Eighth Embodiment

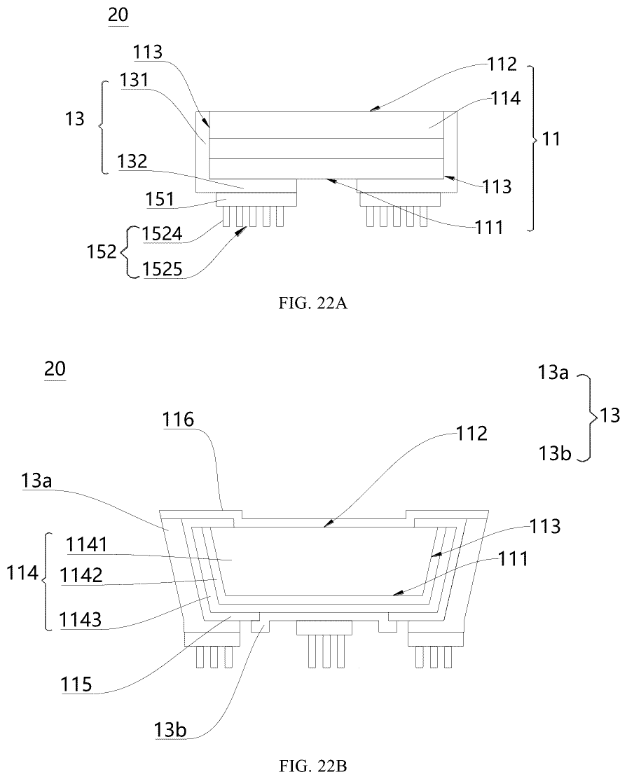

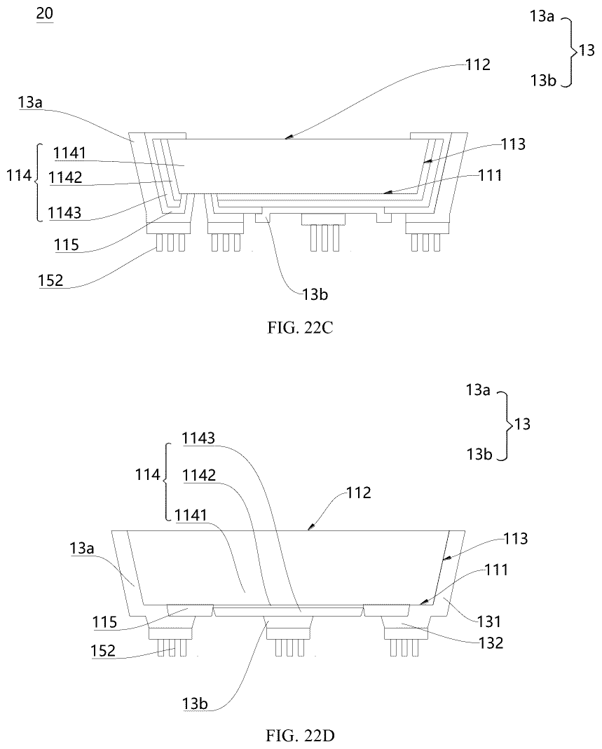

Referring to FIG. 21 and FIG. 22A, the eighth embodiment of the disclosure provides a microelectronic component 20 including a microelectronic element 11 and a chip electrode 13, having a first surface 111 and a second surface 112 opposite to each other along a first direction and side surfaces 113 adjacent to the first surface 111 and the second surface 112. The microelectronic element 11 includes multiple semiconductor layers 114 stacked along the first direction. The chip electrode 13 is electrically connected to the microelectronic element 11 and is at least partially arranged on the side surface 113 of the microelectronic element 11. The chip electrode 13 has an accommodation fixing structure 152 which can be inserted and fixed by a substrate electrode 14 on a bonding substrate 12, so that the microelectronic element 11 can be bonded to the bonding substrate 12.

The microelectronic element 11, for example, is a micro light-emitting device, specifically, such as a micro-LED chip. The microelectronic element 11 contains multiple semiconductor layers 114, such as a first semiconductor layer 1141, an active layer 1142 and a second semiconductor layer 1143 (referring to FIG. 22B to 22d). The first semiconductor layer 1141 is, for example, an N-type semiconductor layer, the active layer 1142 is, for example, an MQW layer, the second semiconductor layer 1143 is, for example, a P-type semiconductor layer, etc. In some embodiments, multiple layers of N-type semiconductor layer, MQW layer and P-type semiconductor layer can be arranged. Of course, in addition to the multiple semiconductor layers 114, the microelectronic element 11 may, for example, include a reflective layer, an ohmic contact layer, an insulation layer 115, etc. In some embodiments, the microelectronic element 11 contains layers that can be set up with reference to the structure of a traditional micro-LED chip. The first surface 111 and the second surface 112 are two surfaces of the microelectronic element 11 that are opposite each other in the stacking direction. The chip electrode 13 may include a first polar electrode 13a connected to the first semiconductor layer 1141 and a second polar electrode 13b connected to the second semiconductor layer 1143. The first polar electrode 13a is an N electrode when the first semiconductor layer 1141 is an N-type semiconductor layer and the second polar electrode 13b is a P electrode when the second semiconductor layer 1143 is a P-type semiconductor layer. The chip electrode 13 is at least partially arranged on the side surface 113, which may be the N electrode all on the side surface 113, or the P electrode all on the first surface 111, or both the N electrode and the P electrode are all or partially arranged on the side surface 113. For example, the N electrode and the P electrode are arranged on opposite or adjacent the side surfaces 113, which can increase the distance between the N electrode and the P electrode and reduce the mutual interference between the N electrode and the P electrode.

In this embodiment, the part of the chip electrode 13 located on the side surface 113 can increase the area of the chip electrode 13, enhance the conductive effect, and increase the distance between the N electrode and the P electrode to reduce interference. Moreover, by setting the accommodation fixing structure 152 on the chip electrode 13, the chip electrode 13 can be bonded to the bonding substrate 12 in the form of insertion connection. In the bonding or repairing process, the heating welding method can be avoided, or the test can be carried out first after bonding. After the test, the bonding of the microelectronic component 20 is performed on the pixels to be repaired, and after the repair is completed, all the microelectronic components 20 bonded on the bonding backplane 30 can be welded uniformly, so that the interference to the adjacent pixels can be avoided.

In some embodiments, the chip electrode 13 includes a chip electrode side part 131 arranged on the side surface 113 and a chip electrode bottom part 132 arranged on the first surface 111, the chip electrode bottom part 132 is connected to the chip electrode side part 131, and the accommodation fixing structure 152 is formed on the side of the chip electrode bottom part 132 facing away from the first surface 111. In this embodiment, the accommodation fixing structure 152 is specifically arranged on the chip electrode bottom part 132, which can ensure the width or area required for the setting of the accommodation fixing structure 152, and has the effects of ensuring the stability of the accommodation fixing structure 152 and facilitating the insertion.

Specifically, the chip electrode 13 includes a conductive substrate 151 and an accommodation fixing structure 152 arranged on the conductive substrate 151.

Referring to FIG. 21, the accommodation fixing structure 152 includes a conductive side wall 1521, a flexible structure 1522 and a conductive sheet 1523. The conductive side wall 1521 is enclosed on the conductive substrate 151 to form a filling cavity 1526, and conductive side wall 1521 is electrically connected to the conductive substrate 151. The flexible structure 1522 is filled in the filling cavity 1526, the conductive sheet 1523 is covered on the side of the flexible structure 1522 facing away from the conductive substrate 151, and the conductive sheet 1523 is electrically connected to the conductive side wall 1521. As for the specific arrangement of the conductive side wall 1521, the flexible structure 1522 and the conductive sheet 1523, reference may be made to the description in the seventh embodiment, and details are not repeated here.

Referring to FIG. 22A, the accommodation fixing structure 152 is defined with an accommodation cavity 1525. The accommodation fixing structure 152 includes multiple nanorods 1524 arranged spaced apart from each other, and gaps between the multiple nanorods 1524 forms the accommodation cavity 1525. As for the specific arrangement of the multiple nanorods 1524, reference may be made to the description in the seventh embodiment, and details are not repeated here.

Referring to FIG. 22B, in some embodiments, the multiple semiconductor layers 114 each include a first semiconductor layer 1141, an active layer 1142, and a second semiconductor layer 1143, having a first surface 111, a second surface 112, and side surfaces 113. The active layer 1142 covers the first surface 111 and the side surfaces 113. The second semiconductor layer 1143 covers the active layer 1142. Taking the first semiconductor layer 1141 as a hexahedral structure, the active layer 1142 covers five surfaces of the first semiconductor layer 1141 except the second surface 112. The second semiconductor layer 1143 is coated on the active layer 1142 in the same manner as the active layer 1142 covering the first semiconductor layer 1141.

In some embodiments, the microelectronic element 11 further includes an insulation layer 115, covering on the second semiconductor layer 1143. The chip electrode 13 includes a first polar electrode 13a and a second polar electrode 13b. The second polar electrode 13b is electrically connected to the second semiconductor layer 1143 through the insulation layer 115. The first polar electrode 13a is insulated with the second semiconductor layer 1143 through the insulation layer 115, and the first polar electrode 13a is electrically connected to the first semiconductor layer 1141. At least part of at least one of the first polar electrodes 13a and the second polar electrodes 13b is arranged on the side surface 113.

Specifically, for example, referring to FIG. 22B, the insulation layer 115 includes an insulation layer bottom part corresponding to the first surface 111, an insulation layer side part corresponding to the side surface 113, and the insulation layer bottom part is defined with an opening for the second polar electrode 13b to pass through, so that the second polar electrode 13b can be arranged on the side of the first surface 111 and connected to the second semiconductor layer 1143. The first polar electrode 13a is partially covered on the side of the side surface 113, and partially extended to the side of the first surface 111, and the first polar electrode 13a and the second semiconductor layer 1143 are insulated by the insulation layer 115. Referring to FIG. 22B, the insulation layer 115, for example, further includes an insulation layer top part corresponding to the second surface 112, the insulation layer top part may be defined with an opening, a transparent electrode 116 may be provided on the second surface 112 and connected to the first semiconductor layer 1141 through the insulation layer top part, and the transparent electrode 116 extends to the end of the first polar electrode 13a close to the second surface 112 and the first polar electrode 13a, thus the connection between the first polar electrode 13a and the first semiconductor layer 1141 can be realized. Referring to FIG. 22B, the parts of the first polar electrode 13a and the second polar electrode 13b arranged on the side of the first surface 111 facing away from the second surface 112 are provided with the accommodation fixing structures 152, respectively, so as to realize that the microelectronic component 20 can be bonded to the bonding substrate 12. The light emitted by the microelectronic element 11 can be emitted through the transparent electrode 116 from the side of the second surface 112 facing away from the first surface 111.

Referring to FIG. 22C, in some embodiments, the transparent electrode 116 may not be provided, the part of the second semiconductor layer 1143 and the active layer 1142 located on the first surface 111 is defined with guide hole, the insulation layer 115 extends to the side wall of the guide hole, and the part of the first polar electrode 13a extending into the guide hole is connected to the first semiconductor layer 1141 and the part of the first polar electrode 13a extending to the side wall of the guide hole is insulated with the active layer 1142 and the second semiconductor layer 1143 through the insulation layer 115.

In other embodiments, referring to FIG. 22D, in the microelectronic element 11, the first semiconductor layer 1141 has a first surface 111, a second surface 112, and side surfaces 113. The active layer 1142 and the second semiconductor layer 1143 are sequentially layered on the first surface 111. Orthographic areas of the active layer 1142 and the second semiconductor layer 1143 on the first surface 111 are smaller than the area of the first surface 111. The chip electrode 13 includes a first polar electrode 13a and a second polar electrode 13b; The second electrode 13b is arranged on the side of the second semiconductor layer 1143 facing away from the active layer 1142 and is electrically connected to the second semiconductor layer 1143. The first polar electrode 13a is at least partially arranged on the side surface 113 and electrically connected to the first semiconductor layer 1141.

In some embodiments, referring to FIG. 22D, the microelectronic element 11 further includes an insulation layer 115 arranged on the first surface 111, and the first polar electrode 13a includes a chip electrode side part 131 arranged on the side surface 113 and a chip electrode bottom part 132 arranged on the insulation layer 115 facing away from the first surface 111. An accommodation fixing structure can be arranged on the chip electrode bottom part 132 and on the second polar electrode 13b individually to realize that the microelectronic component 20 can be bonded to the bonding substrate 12. It should be noted that the microelectronic element 11 described in the seventh embodiment above may have the specific structure of the microelectronic element 11 in any of the microelectronic components illustrated FIG. 22B to FIG. 22D. The accommodation fixing structure 152 including the multiple nanorods 1524 illustrated FIG. 22B to FIG. 22D can also be replaced by an accommodation fixing structure including the conductive side wall 1521, the flexible structure 1522 and the conductive sheet 1523, which will not be repeated herein.

The microelectronic component 20 provided in the eighth embodiment of the disclosure is provided with the accommodation fixing structure 152 on the chip electrode 13, which has the same beneficial effects as the bonding assembly 10 in the seventh embodiment above.

### Ninth Embodiment

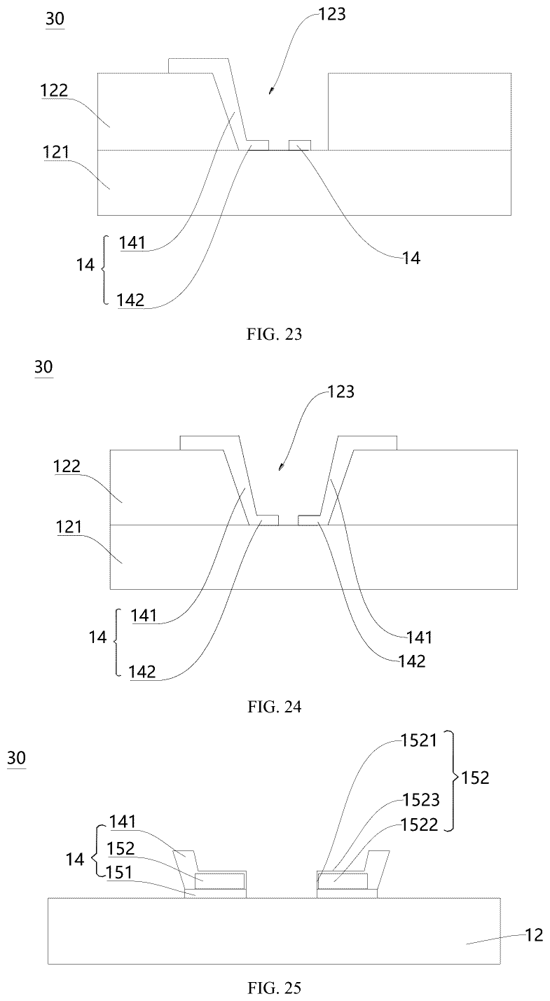

Referring to FIG. 23 to FIG. 26, the ninth embodiment of the disclosure provides a bonding backplane 30, including a bonding substrate 12 and a substrate electrode 14, and the substrate electrode 14 is arranged on a side of the bonding substrate 12 and electrically connected to the bonding substrate 12. An accommodation fixing structure is formed on the bonding backplane 30, and the accommodation fixing structure can be inserted and fixed by an insertion structure formed on a microelectronic component 20, so that the microelectronic component 20 can be bonded to the bonding substrate 12.

In some embodiments, the substrate electrode 14 includes a substrate electrode side part 141 extending along a direction facing away from the bonding substrate 12, and the substrate electrode side part 141 is used for bonding to the chip electrode side part 131 on the microelectronic component 20.

The bonding substrate 12, for example, is a micro-LED driving circuit board, the bonding substrate 12 is provided with two substrate electrodes 14 corresponding to one micro-LED chip. The bonding substrate 12 is provided with multiple substrate electrodes 14 that can bond multiple micro-LED chips. Two sets of substrate electrodes 14 can be arranged at a corresponding pixel position on the bonding substrate 12, with one set acting as spare electrodes for the other set.

In this embodiment, by setting the accommodation fixing structure on the bonding backplane 30, the bonding connection of the microelectronic component 20 can be realized. In the bonding or repair process, the heating welding method can be avoided, or the test can be carried out first after bonding. After the test, the bonding of the microelectronic component 20 is performed on the pixels to be repaired, and after the repair is completed, all the microelectronic components 20 bonded on the bonding backplane 30 can be welded uniformly, so that the interference to the adjacent pixels can be avoided. In addition, when the bonding backplane 30 has the accommodation fixing structure, the repair process is simpler and more feasible than the repair scheme using conductive adhesive, which can avoid the step of adding adhesive material. Moreover, the substrate electrode 14 has a substrate electrode side part 141 that can be fixed with the chip electrode side part 131 on the microelectronic component 20, which can increase the bonding area, improve the bonding area and conductive effect.

The accommodation fixing structure 152 can be formed on the bonding substrate 12 or on the substrate electrode 14.

In some embodiments, referring to FIG. 23 and FIG. 24, a substrate groove 123 is formed on the bonding substrate 12, the substrate electrode side part 141 is located on the side wall of the substrate groove 123, and the substrate groove 123 is used as an accommodation fixing structure 152. The microelectronic component 20 can be directly inserted into the substrate groove 123 and bonded with the substrate electrode 14.

Specifically, the bonding substrate 12 includes a driving circuit board 121 and a pixel definition layer 122 arranged on the driving circuit board 121. The driving circuit board 121 is provided with a driving circuit for driving the microelectronic component 20 to operate, the substrate electrode 14 is electrically connected to the driving circuit, and the substrate groove 123 is specifically formed on the pixel definition layer 122. The structure is simpler by opening the substrate groove 123 directly on the bonding substrate 12 to realize embedded bonding.

Referring to FIG. 23 and FIG. 24, the position and number of the substrate electrode side part 141 can be designed according to the position of the chip electrode side part 131 of chip electrode 13 on the microelectronic component 20 to be bonded, and this embodiment is not limited.

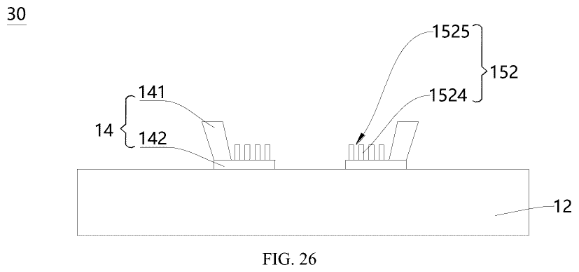

In some embodiments, referring to FIG. 25 and FIG. 26, the substrate electrode 14 includes a substrate electrode side part 141 and a substrate electrode bottom part 142, and the substrate electrode side part 141 extends from the substrate electrode bottom part 142 along a direction facing away from the bonding substrate 12. The accommodation fixing structure 152 is formed on the substrate electrode bottom part 142.

In some embodiments, the accommodation fixing structure 152 may be a structure as illustrated FIG. 25, including a conductive side wall 1521, a flexible structure 1522, and a conductive sheet 1523. The conductive side wall 1521 is enclosed on the conductive substrate 151 to form a filling cavity 1526, which is electrically connected to the conductive substrate 151. The flexible structure 1522 is filled in the filling cavity 1526, the conductive sheet 1523 is covered on the side of the flexible structure 1522 facing away from the conductive substrate 151, and the conductive sheet 1523 is electrically connected to the conductive side wall 1521. As for the specific arrangement of the conductive side wall 1521, the flexible structure 1522 and the conductive sheet 1523, reference may be made to the description in the seventh embodiment, and details are not repeated here.

In some embodiments, the accommodation fixing structure 152, as illustrated FIG. 26, includes multiple nanorods 1524 arranged spaced apart from each other, and gaps between the multiple nanorods 1524 form an accommodation cavity 1525. As for the specific arrangement of the multiple nanorods 1524, reference may be made to the description in the seventh embodiment, and details are not repeated here.

The bonding backplane 30 provided in the ninth embodiment of the disclosure is provided with the accommodation fixing structure 152 on the substrate electrode 14, which has the same beneficial effects as the bonding assembly 10 in the seventh embodiment above.

The above description is only the illustrated embodiments of the disclosure, and is not intended to limit the disclosure in any form. Although the disclosure has been disclosed by the illustrated embodiments, it is not intended to limit the disclosure. Any person skilled in the art can make some changes or modifications into an equivalent embodiment by using the technical content disclosed above without departing from the scope of the technical solution of the disclosure. Any modifications, equivalent variations, and embellishments made to the above embodiments based on the technical essence of the disclosure without departing from the content of the technical solution of the disclosure still fall within the scope of the technical solution of the disclosure.

What is claimed is:

1. A bonding assembly, comprises:
a microelectronic component, comprising: a microelectronic element and a chip electrode, wherein the chip electrode is electrically connected to the microelectronic element; and
a bonding backplane, comprising: a bonding substrate and a substrate electrode, wherein the substrate electrode is arranged on a side of the bonding substrate and electrically connected to the bonding substrate;
wherein one of the microelectronic component and the bonding backplane is provided with an accommodation fixing structure, the other of the microelectronic component and the bonding backplane is provided with an insertion structure, the accommodation fixing structure is configured to be capable of being inserted by the insertion structure and fix the insertion structure, so as to make the chip electrode and the substrate electrode be bonded to each other to realize an electrical connection between the microelectronic element and the bonding substrate.

2. The bonding assembly as claimed in claim 1, wherein the accommodation fixing structure is arranged on one of the substrate electrode and the chip electrode, and the insertion structure is arranged on the other of the substrate electrode and the chip electrode.

3. The bonding assembly as claimed in claim 2, wherein the accommodation fixing structure comprises a plurality of first nanorods, the plurality of first nanorods are arranged spaced apart from each other, and gaps between the plurality of first nanorods form an accommodation cavity to accommodate the insertion structure.

4. The bonding assembly as claimed in claim 3, wherein the insertion structure comprises a plurality of second nanorods, the plurality of second nanorods are arranged spaced apart from each other, and a gap distance between any two adjacent first nanorods of the plurality of first nanorods is equal to a width of a corresponding one of the plurality of second nanorods.

5. The bonding assembly as claimed in claim 2, wherein the accommodation fixing structure comprises a conductive side wall, a flexible structure and a conductive sheet; the conductive side wall is enclosed on a conductive substrate to form a filling cavity, and is electrically connected to the conductive substrate; the flexible structure is filled in the filling cavity; the conductive sheet is covered on a side of the conductive side wall facing away from the conductive substrate, and the conductive sheet is electrically connected to the conductive side wall.

6. The bonding assembly as claimed in claim 5, wherein the insertion structure comprises:
a solder layer; and
a conductive spike, arranged on a side of the solder layer and being capable of penetrating through the conductive sheet and piercing into the flexible structure to be electrically connected to the conductive side wall via the conductive sheet.

7. The bonding assembly as claimed in claim 5, wherein a thickness of the conductive sheet is less than 1 micrometer.

8. The bonding assembly as claimed in claim 1, wherein the microelectronic element comprises a first surface and a second surface opposite to each other along a first direction, and side surfaces adjacent to the first surface and the second surface; the microelectronic element further comprises a plurality of semiconductor layers layered along the first direction; and the chip electrode is at least partially arranged on the side surface of the microelectronic element.

9. The bonding assembly as claimed in claim 8, wherein a substrate groove is defined on the bonding substrate, and the substrate electrode is at least partially located in the substrate groove; the microelectronic element and the chip electrode together serve as the insertion structure, the substrate groove serves as the accommodation fixing structure, and the microelectronic element and the chip electrode are inserted together into the substrate groove to allow the chip electrode and the substrate electrode to be bonded to each other.

10. The bonding assembly as claimed in claim 9, wherein the chip electrode comprises a chip electrode side part located on the side surface; the substrate electrode comprises a substrate electrode side part covered on a side wall of the substrate groove, and the substrate electrode side part is in contact with the chip electrode side part.

11. The bonding assembly as claimed in claim 10, wherein the chip electrode further comprises a chip electrode bottom part connected to the chip electrode side part, and the chip electrode bottom part is located on the first surface; the substrate electrode further comprises a substrate electrode bottom part connected to the substrate electrode side part and located at a bottom of the substrate groove, and the substrate electrode bottom part is located on a side of the chip electrode bottom part opposite to the microelectronic element and is in contact with the chip electrode bottom part.

12. The bonding assembly as claimed in claim 8, wherein the chip electrode comprises a chip electrode side part located on the side surface and a chip electrode bottom part located on the first surface; the substrate electrode comprises a substrate electrode side part and a substrate electrode bottom part, and the substrate electrode side part extends from the substrate electrode bottom part along a direction facing away from the bonding substrate; the accommodation fixing structure is arranged on one of the chip electrode bottom part and the substrate electrode bottom part, and the insertion structure is arranged on the other of the chip electrode bottom part and the substrate electrode bottom part, so as to make the chip electrode bottom part and the substrate electrode bottom part be capable of being bonded together, with the chip electrode side part being in contact with the substrate electrode side part and positioning the microelectronic component.

13. A microelectronic component, comprises:
a microelectronic element; and
a chip electrode, electrically connected to the microelectronic element, wherein the chip electrode comprises a conductive substrate and an accommodation fixing structure arranged on the conductive substrate, the accommodation fixing structure is configured to be capable of being inserted by an insertion structure arranged on a substrate electrode of a bonding substrate and fix the insertion structure, so as to make the chip electrode be bonded to the substrate electrode to thereby make the microelectronic element be electrically connected to the bonding substrate.

14. The microelectronic component as claimed in claim 13, wherein the accommodation fixing structure comprises a conductive side wall, a flexible structure and a conductive sheet; the conductive side wall is enclosed on a conductive substrate to form a filling cavity, and is electrically connected to the conductive substrate; the flexible structure is filled in the filling cavity; the conductive sheet is covered on a side of the conductive side wall facing away from the conductive substrate, and the conductive sheet is electrically connected to the conductive side wall.

15. The microelectronic component as claimed in claim 13, wherein the accommodation fixing structure comprises a plurality of nanorods arranged on a side of the conductive substrate facing away from the microelectronic element; the plurality of nanorods are arranged spaced apart from each other, and gaps between the plurality of nanorods form an accommodation cavity to accommodate the insertion structure.

16. The microelectronic component as claimed in claim 13, wherein the microelectronic element comprises a first surface and a second surface opposite to each other along a first direction, and side surfaces adjacent to the first surface and the second surface; the microelectronic element further comprises a plurality of semiconductor layers layered along the first direction; and the chip electrode is electrically connected to the microelectronic element and is at least partially arranged on the side surface of the microelectronic element.

17. The microelectronic component as claimed in claim 16, wherein the chip electrode comprises a chip electrode side part located on the side surface and a chip electrode bottom part arranged on the first surface, the chip electrode bottom part is connected to the chip electrode side part, and the accommodation fixing structure is arranged on the chip electrode bottom part facing away from the first surface.

18. The microelectronic component as claimed in claim 16, wherein the plurality of semiconductor layers each comprises a first semiconductor layer, an active layer and a second semiconductor layer; the first semiconductor layer comprises the first surface, the second surface and the side surfaces; the active layer covers the first surface and the side surfaces; and the second semiconductor layer covers the active layer.

19. The microelectronic component as claimed in claim 18, wherein the microelectronic element further comprises an insulation layer covering the second semiconductor layer; the chip electrode comprises a first polar electrode and a second polar electrode; the second polar electrode is electrically connected to the second semiconductor layer by penetrating through the insulation layer; the first polar electrode is insulated with the second semiconductor layer through the insulation layer, and the first polar electrode is electrically connected to the first semiconductor layer; and at least a portion of at least one of the first polar electrode and the second polar electrode is arranged on the side surface.

20. The microelectronic component as claimed in claim 16, wherein the plurality of semiconductor layers each comprises a first semiconductor layer, an active layer and a second semiconductor layer; the first semiconductor layer comprises the first surface, the second surface and the side surfaces; the active layer and the second semiconductor layer are sequentially layered on the first surface; an orthographic area of the active layer on the first surface and an orthographic area of the second semiconductor layer on the first surface are less than an area of the first surface; the chip electrode comprises a first polar electrode and a second polar electrode; the second polar electrode is arranged on a side of the second semiconductor layer facing away from the active layer and is electrically connected to the second semiconductor layer; and the first polar electrode is at least partially arranged on the side surface and electrically connected to the first semiconductor layer.

21. A bonding backplane, comprises:
a bonding substrate; and
a substrate electrode, electrically connected to the bonding substrate;
wherein the bonding backplane further comprises an accommodation fixing structure, and the accommodation fixing structure is configured to be inserted by an insertion structure of a microelectronic component and fix the insertion structure, so as to make the substrate electrode be bonded to a chip electrode in the microelectronic component to make the bonding substrate be electrically connected to the microelectronic component.

22. The bonding backplane as claimed in claim 21, wherein the substrate electrode comprises a conductive substrate and the accommodation fixing structure arranged on the conductive substrate, and the accommodation fixing structure is configured to be capable of being inserted by the insertion structure located on the chip electrode and fix the insertion structure.

23. The bonding backplane as claimed in claim 22, wherein the accommodation fixing structure comprises a conductive side wall, a flexible structure and a conductive sheet; the conductive side wall is enclosed on the conductive substrate to form a filling cavity, and is electrically connected to the conductive substrate; the flexible structure is filled in the filling cavity; the conductive sheet is covered on a side of the conductive side wall facing away from the conductive substrate, and the conductive sheet is electrically connected to the conductive side wall.

24. The bonding backplane as claimed in claim 22, wherein the accommodation fixing structure comprises: a plurality of nanorods arranged on a side of the conductive substrate facing away from the bonding substrate; the nanorods are arranged spaced apart from each other, and gaps between the plurality of nanorods form an accommodation cavity accommodate the insertion structure.

25. The bonding backplane as claimed in claim 21, wherein the substrate electrode comprises a substrate electrode side part extending along a direction facing away from the bonding substrate, a substrate groove is defined on the bonding substrate, the substrate electrode side part is located on a side wall of the substrate groove, and the substrate groove serves as the accommodation fixing structure.

26. The bonding backplane as claimed in claim 21, wherein the substrate electrode comprises a substrate electrode side part and a substrate electrode bottom part, the substrate electrode side part extends from the substrate electrode bottom part along a direction facing away from the bonding substrate, and the accommodation fixing structure is arranged on the substrate electrode bottom part.
